(19) United States
(12) Patent Application Publication
(10) Pub. No.: US 2025/0048894 A1
(43) Pub. Date: Feb. 6, 2025

(54) DISPLAY SUBSTRATE, DISPLAY APPARATUS, AND METHOD OF FABRICATING DISPLAY SUBSTRATE

(71) Applicants: Beijing BOE Technology Development Co., Ltd., Beijing (CN); BOE Technology Group Co., Ltd., Beijing (CN)

(72) Inventor: Zhuo Li, Beijing (CN)

(73) Assignees: Beijing BOE Technology Development Co., Ltd., Beijing (CN); BOE Technology Group Co., Ltd., Beijing (CN)

(21) Appl. No.: 18/264,018

(22) PCT Filed: Nov. 9, 2022
(86) PCT No.: PCT/CN2022/130865

§ 371 Date: Aug. 2, 2023

(51) Int. Cl. H10K 59/80; G02B 5/20; H10K 59/38; H10K 101/00; H10K 102/00

(52) U.S. Cl. CPC H10K 59/877; G02B 5/201; H10K 59/38; H10K 2101/80; H10K 2102/331

(57) ABSTRACT

A display substrate is provided. The display substrate includes a quantum dots layer having a plurality of quantum dots. The quantum dots layer includes a plurality of quantum dots blocks respectively in a plurality of first apertures. A respective quantum dots block of the plurality of quantum dots blocks includes a first region and a second region. A concentration of a respective product of a respective reactant produced by a respective reaction in the first region is greater than a concentration of the respective product of the respective reactant produced by the respective reaction in the second region. The respective reaction is one of a dimerization, oligomerization, polymerization, a condensation reaction, or any combination thereof.

### TECHNICAL FIELD

The present invention relates to display technology, more particularly, to a display substrate, a display apparatus, and a method of fabricating a display substrate.

### BACKGROUND

Quantum dots material has excellent optical and electrical properties, including a narrow emission peak (with a half-peak width of approximately 30 nm), a tunable spectrum (ranging from visible light to infrared light), high photochemical stability, and a low starting voltage. Wavelengths of light emitted from quantum dots materials are tunable at least in part based on the particle sizes of the quantum dots. Due to these excellent properties, quantum dots have become a focus of research and development in the fields of display technology.

### SUMMARY

In one aspect, the present disclosure provides a display substrate, comprising a quantum dots layer having a plurality of quantum dots; wherein the quantum dots layer comprises a plurality of quantum dots blocks respectively in a plurality of first apertures; a respective quantum dots block of the plurality of quantum dots blocks comprises a first region and a second region; a concentration of a respective product of a respective reactant produced by a respective reaction in the first region is greater than a concentration of the respective product of the respective reactant produced by the respective reaction in the second region; and the respective reaction is one of a dimerization, oligomerization, polymerization, a condensation reaction, or any combination thereof.

Optionally, a ratio of the respective reactant to the respective product in the second region is greater than a ratio of the respective reactant to the respective product in the first region.

Optionally, the respective reactant is a molecule comprising a dienophile functional group.

Optionally, the respective reactant is a molecule comprising a conjugated diene functional group.

Optionally, the respective reaction is dimerization, and the respective product is a dimerization product of a molecule comprising a dienophile functional group.

Optionally, the respective reaction is a Diels-Alder reaction, and the respective product is a product of the Diels-Alder reaction between a molecule comprising a dienophile functional group and a molecule comprising a conjugated diene functional group.

Optionally, the respective quantum dots block comprises a first respective product produced by a dimerization reaction and a second respective product produced by a Diels-Alder reaction; a concentration of the first respective product in the first region is greater than a concentration of the first respective product in the second region; and a concentration of the second respective product in the first region is greater than a concentration of the second respective product in the second region.

Optionally, the respective reactant is chelated to a quantum dots.

Optionally, the respective reactant comprises a dienophile functional group and a quantum dots chelating group.

Optionally, the respective reactant comprises a conjugated diene functional group and a quantum dots chelating group.

Optionally, the respective product is chelated to a quantum dots.

Optionally, the display substrate further comprises a bank layer defining the plurality of first apertures; wherein the bank layer substantially surrounds the second region; the second region substantially surrounds the first region; and the second region spaces apart the first region from the bank layer.

Optionally, the display substrate further comprises a light scattering layer; wherein the light scattering layer comprises a plurality of light scattering blocks respectively in a plurality of second apertures; a respective light scattering block of the plurality of light scattering blocks includes a third region and a fourth region; and the concentration of the respective product in the third region is greater than the concentration of the respective product in the fourth region.

Optionally, the respective reactant comprises a bis dienophile functional group selected from the group consisting of:

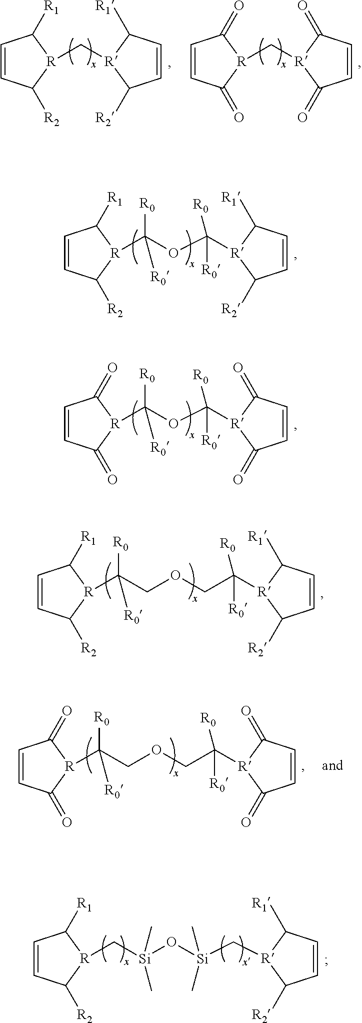

wherein R is nitrogen or —CH; R′ is nitrogen or —CH; R₀, R₀′, R₁, R₁′, R₂, R₂′ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl; and x and x′ are independently a positive integer equal to or greater than 2.

Optionally, the respective reactant comprises a bis dienophile functional group selected from the group consisting of:

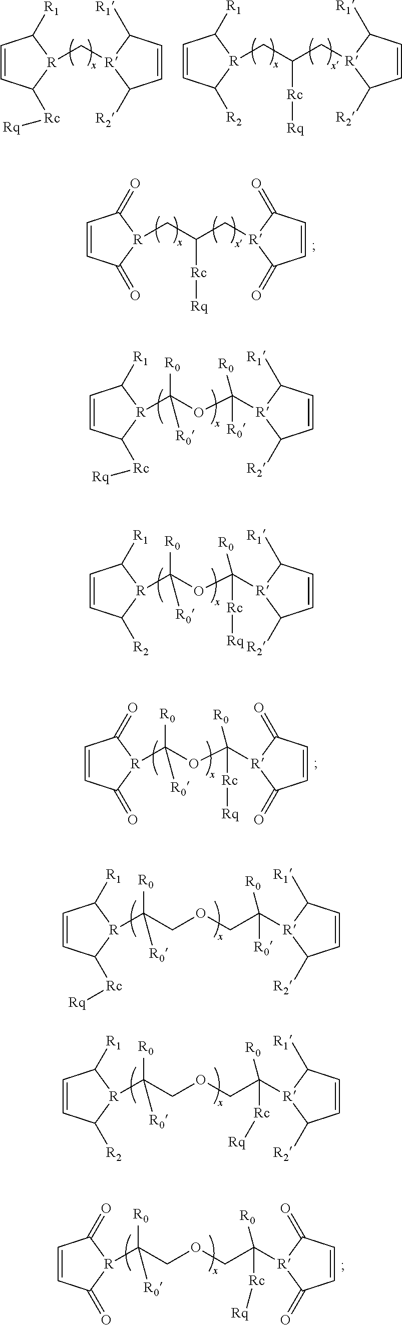

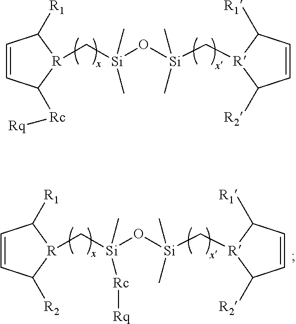

wherein R is nitrogen or —CH; R′ is nitrogen or —CH; R₀, R₀′, R₁, R₁′, R₂, R₂′ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl; x and x′ are independently a positive integer equal to or greater than 2; R_{c} is substituted or unsubstituted alkylene, substituted or unsubstituted alkylene comprising an amide group, substituted or unsubstituted alkylene comprising an ester group, substituted or unsubstituted alkylene comprising a nitrogenous five-membered heterocycle, substituted or unsubstituted heteroalkylene, substituted or unsubstituted cycloalkylene, substituted or unsubstituted heterocycloalkylene, substituted or unsubstituted arylene, or substituted or unsubstituted heteroarylene; and R_{q} stands for a quantum dots chelating group.

Optionally, the respective reactant comprises a conjugated diene functional group selected from the group consisting of:

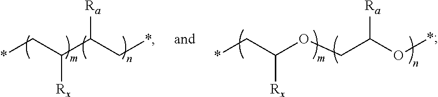

wherein Rₓ stands for the conjugated diene functional group, the one or more reactants further includes a main chain, the conjugated diene functional group Rₓ is connected to the main chain; m is a positive integer, n is zero or a positive integer, 10≤ (m+n)≤100; and Rₐ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

Optionally, Rₐ is selected from the group consisting of hydrogen, substituted or unsubstituted C₁ to C₂₀ alkyl, or substituted or unsubstituted phenyl; Rₓ is selected from the group consisting of:

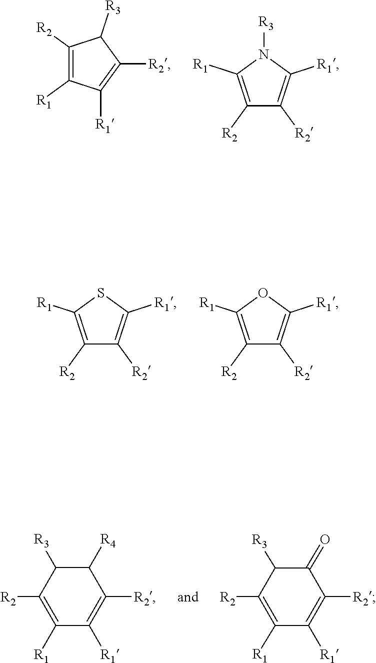

wherein one of R₁, R₁′, R₂, R₂′, R₃, and R₄ is connected to the main chain of the reactant; the one of R₁, R₁′, R₂, R₂′, R₃, and R₄ connected to the main chain of the reactant is substituted or unsubstituted alkylene, substituted or unsubstituted alkylene comprising an amide group, substituted or unsubstituted alkylene comprising an ester group, substituted or unsubstituted alkylene comprising a nitrogenous five-membered heterocycle; and the other five of R₁, R₁′, R₂, R₂′, R₃, and R₄ that are not connected to the main chain of the reactant are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

Optionally, the respective reactant comprises a conjugated diene functional group selected from the group consisting of:

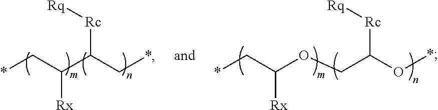

wherein Rₓ stands for the conjugated diene functional group, the one or more reactants further includes a main chain, the conjugated diene functional group Rₓ is connected to the main chain; m is a positive integer, n is a positive integer, 1≤ n≤10, 10≤ (m+n)≤50; and R_{c} is substituted or unsubstituted alkylene, substituted or unsubstituted alkylene comprising an amide group, substituted or unsubstituted alkylene comprising an ester group, substituted or unsubstituted alkylene comprising a nitrogenous five-membered heterocycle, substituted or unsubstituted heteroalkylene, substituted or unsubstituted cycloalkylene, substituted or unsubstituted heterocycloalkylene, substituted or unsubstituted arylene, or substituted or unsubstituted heteroarylene; and R_{q} stands for a quantum dots chelating group.

Optionally, the respective quantum dots block is absent of any chemical initiator of the respective reaction.

In another aspect, the present disclosure provides a display apparatus, comprising the display substrate described herein or fabricated by a method described herein, and a light emitting substrate.

In another aspect, the present disclosure provides a method of fabricating a display substrate, comprising forming a quantum dots layer having a plurality of quantum dots; wherein forming the quantum dots layer comprises disposing a quantum dots ink solution into a plurality of first apertures; precuring the quantum dots ink solution in the plurality of first aperture to obtain a plurality of precured quantum dots blocks; initiating a respective reaction in a first region of a respective precured quantum dots block of the plurality of precured quantum dots blocks without initiating the respective reaction in a second region of the respective precured quantum dots block; and curing the plurality of precured quantum dots blocks subsequent to the respective reaction, thereby obtaining a plurality of quantum dots blocks respectively in the plurality of first apertures; wherein a concentration of a respective product of a respective reactant produced by a respective reaction in the first region of a respective quantum dots block of the plurality of quantum dots blocks is greater than a concentration of the respective product of the respective reactant produced by the respective reaction in the second region of the respective quantum dots block; and the respective reaction is one of a dimerization, oligomerization, polymerization, a condensation reaction, or any combination thereof.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a display panel in some embodiments according to the present disclosure.

FIG. 2 is a cross-sectional view along an A-A′ line in FIG. 1.

FIG. 3A to FIG. 3F illustrate a process of fabricating a display substrate in some embodiments according to the present disclosure.

FIG. 4A to FIG. 4F are plan view of a display substrate in each steps of the process depicted in FIG. 3A to FIG. 3F.

FIG. 5A illustrates migration of one or more reactants from a second region to a first region due to a chemical potential gradient.

FIG. 5B illustrates migration of one or more reactants from a lower portion of a first region to an upper portion of the first region due to a chemical potential gradient.

FIG. 6 is a schematic diagram illustrating the structure of a display panel in some embodiments according to the present disclosure.

FIG. 7 is a cross-sectional view along a B-B′ line in FIG. 6.

FIG. 8 is a plan view of a display panel in some embodiments according to the present disclosure.

FIG. 9 is a cross-sectional view of a display panel in some embodiments according to the present disclosure.

FIG. 10 is a cross-sectional view of a display panel in some embodiments according to the present disclosure.

FIG. 11A is a schematic diagram illustrating the structure of a light emitting element in some embodiments according to the present disclosure.

FIG. 11B is a schematic diagram illustrating the structure of a light emitting element in some embodiments according to the present disclosure.

FIG. 11C is a schematic diagram illustrating the structure of a light emitting element in some embodiments according to the present disclosure.

FIG. 12A is a schematic diagram illustrating the structure of a first quantum dots block in some embodiments according to the present disclosure.

FIG. 12B is a schematic diagram illustrating the structure of a second quantum dots block in some embodiments according to the present disclosure.

FIG. 12C is a schematic diagram illustrating the structure of a light scattering block in some embodiments according to the present disclosure.

FIG. 13A to FIG. 13F illustrate a process of fabricating a display substrate in some embodiments according to the present disclosure.

FIG. 14A to FIG. 14F are plan view of a display substrate in each steps of the process depicted in FIG. 13A to FIG. 13F.

FIG. 15A illustrates migration of one or more reactants from a second region to a first region due to a chemical potential gradient.

FIG. 15B illustrates migration of one or more reactants from a lower portion of a first region to an upper portion of the first region due to a chemical potential gradient.

FIG. 15C illustrates migration of one or more reactants from a fourth region to a third region due to a chemical potential gradient.

FIG. 15D illustrates migration of one or more reactants from a lower portion of a first region to an upper portion of the first region due to a chemical potential gradient.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

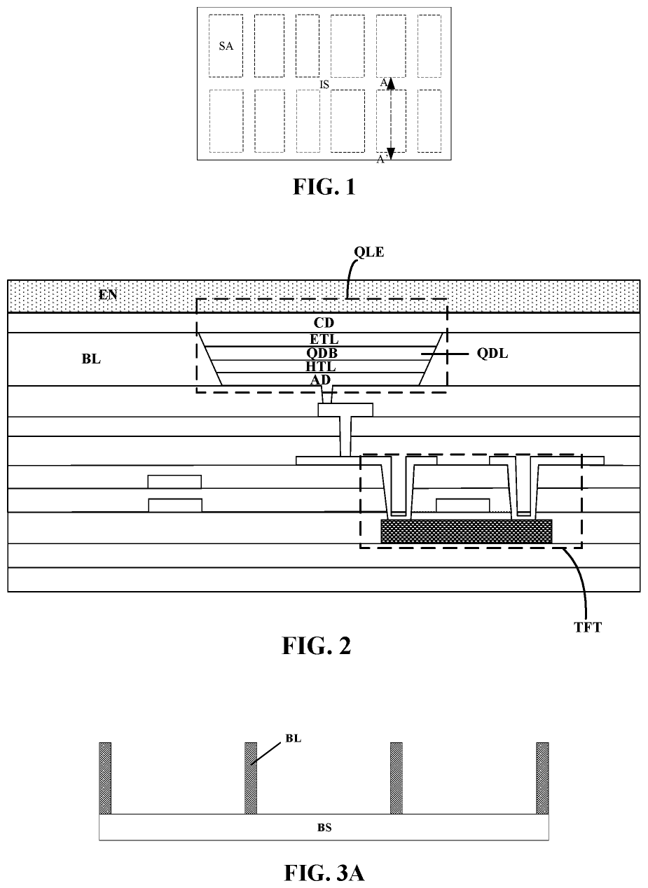

FIG. 1 is a schematic diagram illustrating the structure of a display panel in some embodiments according to the present disclosure. Referring to FIG. 1, the display panel in some embodiments includes a plurality of subpixel region SR and an inter-subpixel region ISR. As used herein, a subpixel region refers to a light emission region of a subpixel, such as a region corresponding to a pixel electrode in a liquid crystal display, or a region corresponding to a light emissive layer in a light emitting diode display panel, or a region corresponding to a quantum dots block in a display panel according to the present disclosure. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel. As used herein, an inter-subpixel region refers to a region between adjacent subpixel regions, such as a region corresponding to a black matrix in a liquid crystal display, or a region corresponding a pixel definition layer in a light emitting diode display panel, or a region corresponding to a bank layer in a display panel according to the present disclosure. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

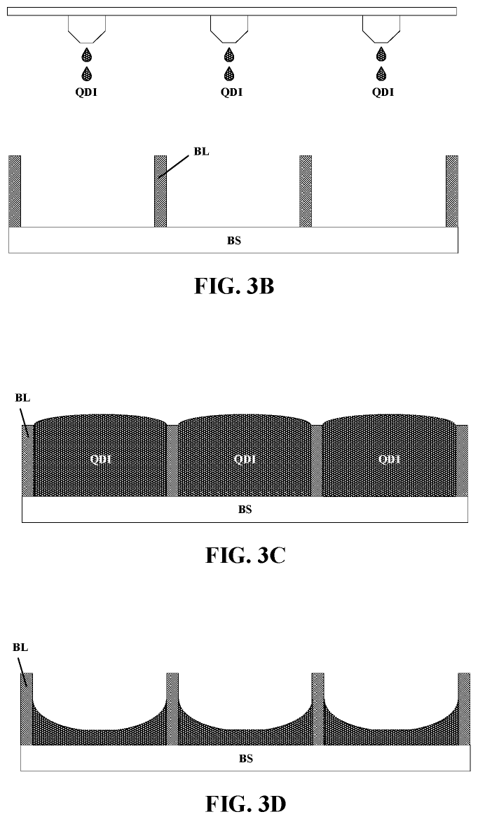

FIG. 2 is a cross-sectional view along an A-A′ line in FIG. 1. Referring to FIG. 2, the display panel in some embodiments includes a plurality of quantum dots light emitting elements QLE and a plurality of thin film transistors TFT for driving light emission in the plurality of quantum dots light emitting elements QLE. In one example, a respective quantum dots light emitting element of the plurality of quantum dots light emitting elements QLE includes an anode AD, a hole transport layer HTL on the anode AD, a quantum dots layer QDL on a side of the hole transport layer HTL away from the anode AD, an electron transport layer ETL on a side of the quantum dots layer QDL away from the hole transport layer HTL, and a cathode CD on a side of the electron transport layer ETL away from the quantum dots layer QDL. The quantum dots layer QDL is a self-emissive layer. As shown in FIG. 2, the quantum dots layer QDL in some embodiments includes a plurality of quantum dots blocks QDB. A respective quantum dots light emitting element of the plurality of quantum dots light emitting elements QLE includes a respective quantum dots block of the plurality of quantum dots blocks QDB.

The inventors of the present disclosure discover that, surprisingly and unexpectedly, a novel structure of the display panel according to the present disclosure can effectively enhance light emission efficiency or light conversion efficiency in the quantum dots layer. Accordingly, the present disclosure provides, inter alia, a display substrate, a display apparatus, and a method of fabricating a display substrate that substantially obviate one or more of the problems due to limitations and disadvantages of the related art. In one aspect, the present disclosure provide a display substrate. In some embodiments, the display substrate includes a quantum dots layer. In some embodiments, the quantum dots layer includes a plurality of quantum dots blocks respectively in a plurality of first apertures. Optionally, a respective quantum dots block of the plurality of quantum dots blocks includes a first region and a second region. Optionally, a concentration of a respective product of a respective reactant produced by a respective reaction in the first region is greater than a concentration of the respective product of the respective reactant produced by the respective reaction in the second region. Optionally, the respective reaction is one of a dimerization, oligomerization, polymerization, a condensation reaction, or any combination thereof.

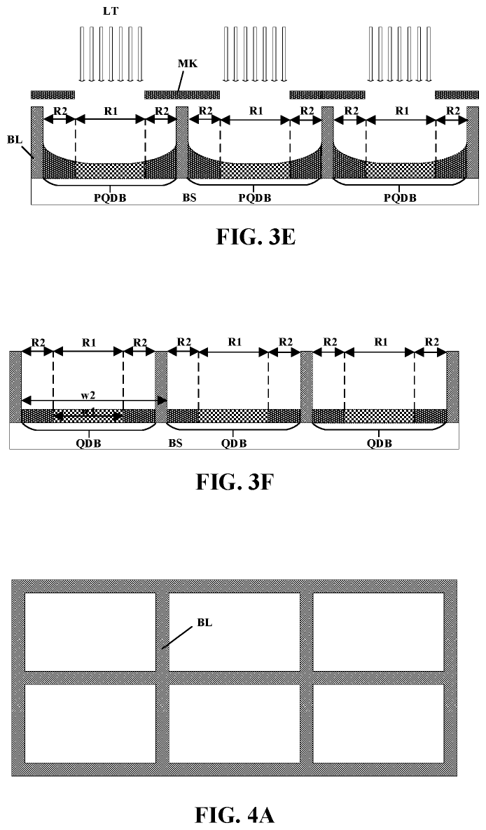

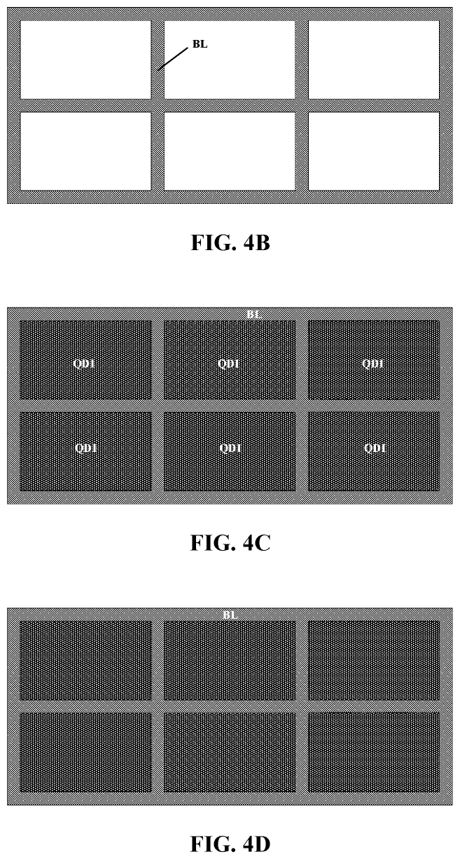

To illustrate the structure of the display substrate of the present disclosure, a process of fabricating the display substrate is briefly described below. FIG. 3A to FIG. 3F illustrate a process of fabricating a display substrate in some embodiments according to the present disclosure. FIG. 4A to FIG. 4G are plan view of a display substrate in each steps of the process depicted in FIG. 3A to FIG. 3F. Referring to FIG. 3A and FIG. 4A, a bank layer BL is formed on a base substrate BS. As shown in FIG. 3A and FIG. 4A, the bank layer BL defines a plurality of apertures. In subsequent steps, a quantum dots layer is disposed at least partially in the plurality of apertures defined by the bank layer BL.

Referring to FIG. 3B and FIG. 4B, a printing process is used to print inks into the plurality of apertures. The inks include a quantum dots material ink QD1 for forming the quantum dots layer.

Referring to FIG. 3C and FIG. 4C, the quantum dots material ink QD1 is printed into apertures in which quantum dots blocks of the quantum dots layer are formed. Various appropriate methods may be used to dispose the quantum dots material. FIG. 3B, FIG. 3C, FIG. 4B, and FIG. 4C depict a printing process. Alternatively, the quantum dots material may be disposed using a coating process.

Referring to FIG. 3D and FIG. 4D, the inks disposed in the plurality of apertures are precured. As shown in FIG. 3D and FIG. 4D, a plurality of precured quantum dots blocks PQDB are formed in the plurality of apertures. As used herein, the term “precured” refers to that a layer has been partially but not completely cured. For example, the layer has not been thermally annealed or has not been baked dry. In one example, a layer in a precured state has at least 50% (e.g., at least 55%, at least 60%, at least 65%, at least 70%, at least 75%, at least 80%, at least 85%, at least 90%, or at least 95%) solvent in the initial deposited solution removed. In another example, a layer in a precured state has at least 45% (e.g., at least 40%, at least 35%, at least 30%, at least 25%, at least 20%, at least 15%, at least 10%, at least 5%, at least 2%, or at least 1%) solvent in the initial deposited solution remaining. As shown in FIG. 3D, the layers in the plurality of apertures show “coffee-ring effect”, e.g., thicker on edge and thinner in the center.

Referring to FIG. 3E and FIG. 4E, to reduce or eliminate the “coffee-ring effect”, a reaction is initiated in a first region R1 of a respective precured quantum dots block of a plurality of precured quantum dots blocks PQDB whereas the reaction is not initiated in a second region R2. In the example depicted in FIG. 3E and FIG. 4E, the reaction is initiated by light (e.g., UV light). For example, a mask plate MK is used to allow light LT to irradiate on the first region R1, and prevent light LT to irradiate on the second region R2. Various alternative methods of initiating a reaction may be used. Examples of reaction initiation methods include heat initiation, electrical initiation, and initiation by a chemical such as an initiator.

The reaction initiated in the first region R1 converts one or more reactants in the first region R1 into one or more products, thereby reducing a number of the one or more reactants in the first region R1. Because the respective precured quantum dots block is not completely cured, it still allows molecules in the respective precured quantum dots block to move, e.g., from the second region R2 into the first region R1. When the number of the one or more reactants in the first region R1 is reduced, a gradient of the one or more reactants is formed between the first region R1 and the second region R2. In one example, the gradient is a chemical potential gradient. The chemical potential refers to a rate of change of free energy of a thermodynamic system with respect to a change in a number of molecules of the one or more reactants that are supplied to or removed from the thermodynamic system. In another example, the gradient is a concentration gradient of the one or more reactants. Due to the gradient of the one or more reactants between the first region R1 and the second region R2, the one or more reactants diffuses or migrates from the second region R2 to the first region R1 as the one or more reactants are converted into the one or more products in the first region R1.

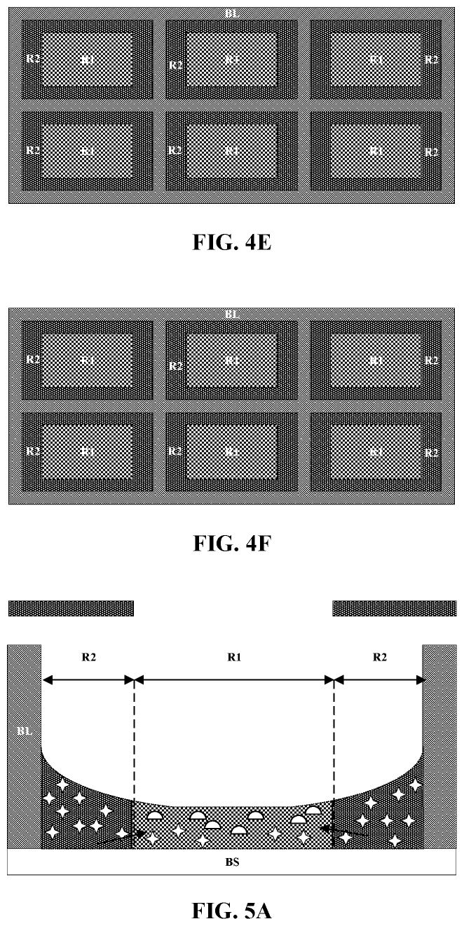

FIG. 5A illustrates migration of one or more reactants from a second region to a first region due to a chemical potential gradient. Referring to FIG. 5A, four-point stars represent the one or more reactants, and half circles represent the one or more products. As shown in FIG. 5A, a reaction is initiated in the first region R1, converting the one or more reactants into the one or more products, thereby creating a gradient (e.g., a chemical potential gradient) between the first region R1 and the second region R2. The reaction is not initiated in the second region R2, for example, light is not irradiated on the second region R2. With the number of the one or more reactants reduced in the first region R1, the one or more reactants (four-point stars) in the second region R2 migrate into the first region R1.

FIG. 5B illustrates migration of one or more reactants from a lower portion of a first region to an upper portion of the first region due to a chemical potential gradient. Referring to FIG. 5B, an upper portion of the first region R1 closer to the incident light is exposed more to the light LT (for example, due to the light funnel effect) as compared to a lower portion of the first region R1 away from the incident light, thus a higher percentage of the one or more reactants in the upper portion is converted into the one or more products as compared to the lower portion, thereby creating a gradient (e.g., a chemical potential gradient) between the upper portion of the first region R1 and the lower portion of the first region R1. With the number of the one or more reactants reduced in the upper portion, the one or more reactants (four-point stars) in the lower portion migrate into the upper portion.

Any one or a combination of the migration of the one or more reactants depicted in FIG. 5A and FIG. 5B results in a “growth” of the first region R1 upward, and/or a shrinkage of the second region R2 downward. For example, due to the chemical potential gradient, a thickness of the first region R1 increases, and/or a thickness of the second region R2 decreases. The end result is a more uniform thickness throughout the respective precured quantum dots block, reducing or eliminating the “coffee-ring effect”. Referring to FIG. 3F and FIG. 4F, the plurality of precured quantum dots blocks are cured to form a plurality of quantum dots blocks QDB. As shown in FIG. 3F and FIG. 4F, a respective quantum dots block of the plurality of quantum dots blocks QDB has a substantially uniform thickness.

In some embodiments, the second region R2 substantially surrounds the first region R₁. As used herein the term “substantially surrounding” refers to surrounding at least 50% (e.g., at least 60%, at least 70%, at least 80%, at least 90%, at least 95%, at least 99%, and 100%) of a perimeter of an area. Optionally, the bank layer substantially surrounds the second region R2, the second region R2 substantially surrounds the first region R1, and the second region R2 spaces apart the first region R1 from the bank layer.

In some embodiments, as discussed further in detail below, the one or more reactants are ligands of a quantum dots in the quantum dots layer. Migration of the one or more reactants drives the quantum dots moving from the second region R2 to the first region R1, and/or moving from the lower portion to the upper portion.

Various appropriate reactants, various appropriate products, and various appropriate reactions may be used in the present disclosure. In some embodiments, the reaction is at least one of a dimerization, oligomerization, polymerization, or condensation reaction, or any combination thereof. As used herein, the term “condensation reaction” refers to a chemical reaction in which two or more molecules are coupled with one another to form a higher molecular weight compound, typically accompanied by the loss of a small molecule such as water or an alcohol. Examples of condensation reactions include Diels-Alder reaction. Accordingly, the one or more reactants could be a monomer in a dimerization reaction, a monomer in an oligomerization reaction, a monomer in a polymerization, a reactant in a condensation reaction, or any combination thereof. Optionally, a reactant may have multiple roles in the reactions, for example, an individual reactant may undergo multiple types of reactions in the fabrication process of the quantum dots layer. In one example, in an individual precured quantum dots block, a reactant may undergo at least two different types of reactions such as dimerization, oligomerization, polymerization, or condensation reaction. In another example, in an individual precured quantum dots block, a reactant is a reactant in a dimerization reaction, and at the same time a reactant in a Diels-Alder reaction.

In some embodiments, the reaction is one that initiated by a non-chemical initiator. Examples of non-chemical initiators include light, heat, pressure, an electrical signal, microwave, and ultrasound. Accordingly, in some embodiments, the quantum dots layer is absent of any chemical initiator (e.g., a photo-initiator molecule) or reaction product thereof.

In some embodiments, the display substrate includes a quantum dots layer. The quantum dots layer includes a plurality of quantum dots blocks QDB respectively in a plurality of apertures. In some embodiments, a respective quantum dots block of the plurality of quantum dots blocks includes a first region R1 and a second region R2.

In some embodiments, a ratio of a respective reactant of the one or more reactants to a respective product of the respective reactant produced by a respective reaction in the second region is greater than a ratio of the respective reactant of the one or more reactants to a respective product of the respective reactant produced by a respective reaction in the first region. Optionally, the ratio of the respective reactant of the one or more reactants to the respective product of the respective reactant produced by the respective reaction in the second region is greater than the ratio of the respective reactant of the one or more reactants to the respective product of the respective reactant produced by a respective reaction in the first region by at least 1%, e.g., by at least 2%, by at least 3%, by at least 4%, by at least 5%, by at least 10%, by at least 15%, by at least 20%, by at least 25%, by at least 30%, by at least 35%, by at least 40%, by at least 45%, by at least 50%, by at least 55%, by at least 60%, by at least 65%, by at least 70%, by at least 75%, by at least 80%, by at least 85%, by at least 90%, by at least 95%, by at least 100%, by at least 150%, by at least 200%, by at least 300%, by at least 400%, or by at least 500%.

In some embodiments, the ratio of the respective reactant of the one or more reactants to the respective product of the respective reactant produced by a respective reaction in the first region has a gradient distribution. A ratio of the respective reactant of the one or more reactants to the respective product of the respective reactant produced by a respective reaction in a first sub-region of the first region is greater than a ratio of the respective reactant of the one or more reactants to the respective product of the respective reactant produced by a respective reaction in a second sub-region of the first region. The second sub-region (e.g., a central sub-region of the first region) is on a side of the first sub-region (e.g., a surrounding sub-region) away from the second region.

In some embodiments, a concentration of the respective product of the respective reactant produced by the respective reaction in the first region is greater than a concentration of the respective product of the respective reactant produced by the respective reaction in the second region. Optionally, the concentration of the respective product of the respective reactant produced by the respective reaction in the first region is greater than the concentration of the respective product of the respective reactant produced by the respective reaction in the second region by at least 1%, e.g., by at least 2%, by at least 3%, by at least 4%, by at least 5%, by at least 10%, by at least 15%, by at least 20%, by at least 25%, by at least 30%, by at least 35%, by at least 40%, by at least 45%, by at least 50%, by at least 55%, by at least 60%, by at least 65%, by at least 70%, by at least 75%, by at least 80%, by at least 85%, by at least 90%, by at least 95%, by at least 100%, by at least 150%, by at least 200%, by at least 300%, by at least 400%, or by at least 500%.

In some embodiments, the concentration of the respective product of the respective reactant produced by the respective reaction in the first region has a gradient distribution. A concentration of the respective product of the respective reactant produced by the respective reaction in a second sub-region of the first region is greater than a concentration of the respective product of the respective reactant produced by the respective reaction in a first sub-region of the first region. The second sub-region (e.g., a central sub-region of the first region) is on a side of the first sub-region (e.g., a surrounding sub-region) away from the second region.

In some embodiments, the concentration of the respective reactant of the respective reaction in the first region has a gradient distribution. A concentration of the respective reactant of the respective reaction in a first sub-region of the first region is greater than a concentration of the respective reactant of the respective reaction in a second sub-region of the first region. The second sub-region (e.g., a central sub-region of the first region) is on a side of the first sub-region (e.g., a surrounding sub-region) away from the second region.

In some embodiments, the respective reactant comprises a ligand chelated to a quantum dots.

In some embodiments, referring to FIG. 3F, in a cross-section perpendicular to a surface of the base substrate and intersecting multiple adjacent quantum dots blocks of the plurality of quantum dots blocks QDB (e.g., a cross-section as shown in FIG. 3F), the first region R1 has a first width w1, and the first region R1 and the second region R2 in combination have a second width w2. In some embodiments, a ratio of the first width w1 to the second width w2 is greater than 1:10, e.g., greater than 2:10, greater than 3:10, greater than 4:10, greater than 5:10, greater than 6:10, greater than 7:10, greater than 8:10, greater than 9:10. In some embodiments, the ratio of the first width w1 to the second width w2 is less than 10:1, e.g., less than 9:1, less than 8:1, less than 7:1, less than 6:1, less than 5:1, less than 4:1, less than 3:1, less than 2:1, less than 1:1, less than 1:2, less than 1:3, less than 1:4, less than 1:5, less than 1:6, less than 1:7, less than 1:8, less than 1:9, or less than 1:10.

In some embodiments, referring to FIG. 3F, the respective quantum dots block of the plurality of quantum dots blocks QDB has a substantially uniform average thickness throughout the first region R1 and the second region R2. In some embodiments, an average thickness of the first region R1 is substantially the same as an average thickness of the second region R2. As used herein, the term “substantially the same” refers to a difference between two values not exceeding 15% of a base value (e.g., one of the two values), e.g., not exceeding 10%, not exceeding 8%, not exceeding 6%, not exceeding 4%, not exceeding 2%, not exceeding 1%, not exceeding 0.5%, not exceeding 0.1%, not exceeding 0.05%, and not exceeding 0.01%, of the base value. Optionally, a difference between the average thickness of the first region R1 and the average thickness of the second region R2 is equal to or less than 15 nm, e.g., equal to or less than 10 nm, equal to or less than 5 nm, equal to or less than 3 nm, equal to or less than 2 nm, or equal to or less than 1 nm. In one example, the difference between the average thickness of the first region R1 and the average thickness of the second region R2 is equal to or less than 5 nm.

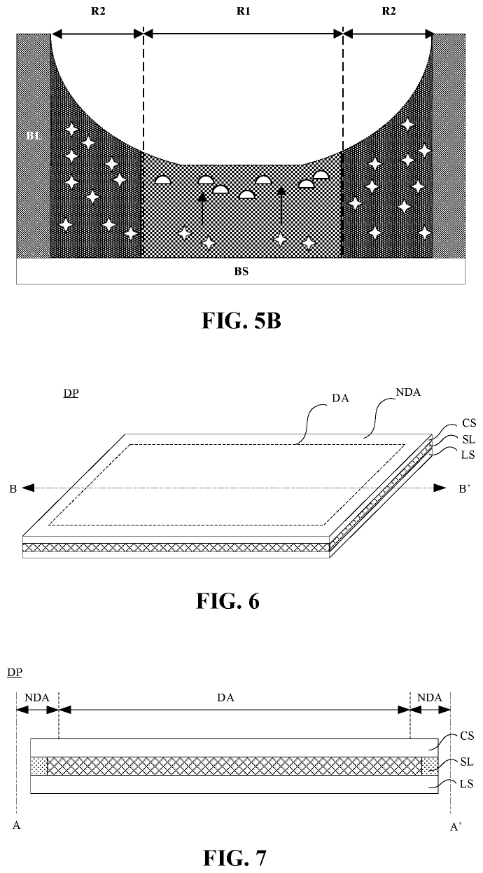

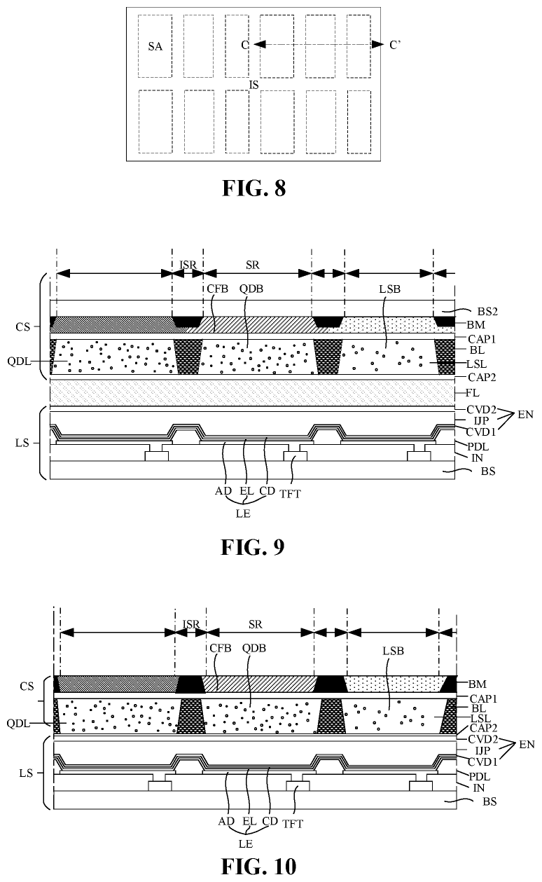

FIG. 6 is a schematic diagram illustrating the structure of a display panel in some embodiments according to the present disclosure. FIG. 7 is a cross-sectional view along a B-B′ line in FIG. 6. Referring to FIG. 6 and FIG. 7, the display panel DP in some embodiments includes a light emitting substrate LS, a counter substrate CS, and a spacer layer SL spacing apart the light emitting substrate LS and the counter substrate CS. The display panel DP includes a display area DA and a non-display area NDA.

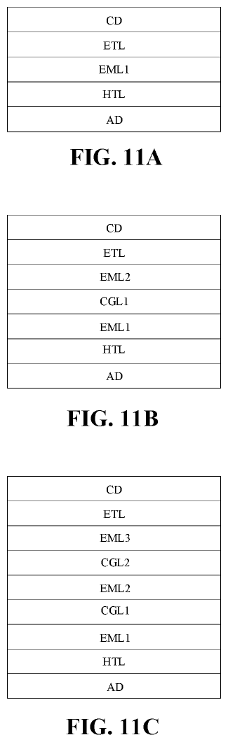

FIG. 8 is a plan view of a display panel in some embodiments according to the present disclosure. Referring to FIG. 8, the display panel in some embodiments includes a plurality of subpixel region SR and an inter-subpixel region ISR. Various appropriate implementations may be practiced to make a display panel of the present disclosure. In one example, a light emitting substrate and a counter substrate are fabricated respectively, and then assembled together using a filler layer into a display panel. In another example, the counter substrate is directly fabricated on the light emitting substrate.

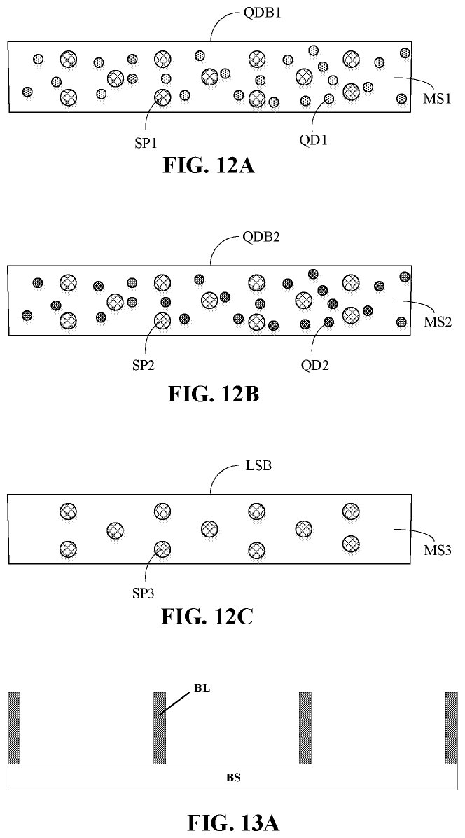

FIG. 9 is a cross-sectional view of a display panel in some embodiments according to the present disclosure. For example, FIG. 9 may be a cross-sectional view along a C-C′ line in FIG. 8. Referring to FIG. 9, the display panel in some embodiments includes a light emitting substrate LS and a counter substrate CS. The light emitting substrate LS and the counter substrate CS are assembled together. In some embodiments, the display panel further includes a filler layer FL between the light emitting substrate LS and the counter substrate CS, assembling the light emitting substrate LS and the counter substrate CS into the display panel. In some embodiments, the light emitting substrate includes a first base substrate BS, and the counter substrate CS includes a second base substrate BS2.

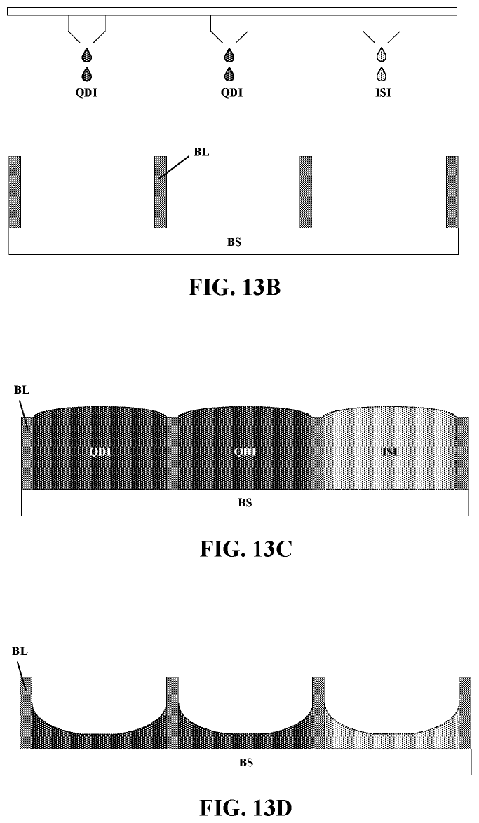

FIG. 10 is a cross-sectional view of a display panel in some embodiments according to the present disclosure. For example, FIG. 10 may be a cross-sectional view along a C-C′ line in FIG. 8. Referring to FIG. 10, the display panel is absent of a filler layer. The counter substrate CS is directly on the light emitting substrate LS, for example, directly on a surface of a second inorganic encapsulating sub-layer CVD2 of the light emitting substrate LS.

Referring to FIG. 9 and FIG. 10, in some embodiments, the light emitting substrate LS includes a first base substrate BS; a plurality of thin film transistor TFT (e.g., transistors in pixel driving circuits) on the first base substrate BS; an insulating layer IN on a side of the plurality of transistor TFT away from the first base substrate BS; a pixel definition layer PDL and a plurality of light emitting elements LE on a side of the insulating layer IN away from the first base substrate BS; and an encapsulating layer EN on a side of the plurality of light emitting elements LE and the pixel definition layer PDL away from the first base substrate BS. A respective light emitting element of the plurality of light emitting elements LE includes an anode AD, a light emitting layer EL on a side of the anode AD away from the first base substrate BS, and a cathode CD on a side of the light emitting layer EL away from the first base substrate BS. In one example, the encapsulating layer EN include a first inorganic encapsulating sub-layer CVD1, an organic encapsulating sub-layer IJP on a side of the first inorganic encapsulating sub-layer CVD1 away from the first base substrate BS, and a second inorganic encapsulating sub-layer CVD2 on a side of the organic encapsulating sub-layer IJP away from the first base substrate BS.

Referring to FIG. 9 and FIG. 10, in some embodiments, the counter substrate CS includes a bank layer BL defining a plurality of apertures, a quantum dots layer QDL and a light scattering layer LSL at least partially in the plurality of apertures defined by the bank layer BL. The quantum dots layer QDL includes a plurality of quantum dots blocks QDB. The light scattering layer LSL includes a plurality of light scattering blocks LSB. The counter substrate CS in some embodiments further includes a color filter CF on the quantum dots layer QDL and the light scattering layer LSL. The color filter CF includes a plurality of color filter blocks CFB. An orthographic projection of a respective color filter block of the plurality of color filter blocks CFB on a base substrate at least partially overlaps with an orthographic projection of a respective quantum dots block or a respective light scattering block on the base substrate. Orthographic projections of adjacent color filter blocks may partially overlap with each other, e.g., along the edges. The counter substrate CS in some embodiments further includes a black matrix BM on a side of the color filter CF away from the quantum dots layer QDL and the light scattering layer LSL. The black matrix BM is in the inter-subpixel region ISR. A respective color filter block, a respective quantum dots block, or a respective light scattering block is at least partially in an individual subpixel region. Optionally, the counter substrate CS includes a first cap layer CAP1 on a side of the color filter CF closer to the bank layer BL, the quantum dots layer QDL, and the light scattering layer LSL. The counter substrate CS optionally includes a second cap layer CAP2 on a side of the bank layer BL, the quantum dots layer QDL, and the light scattering layer LSL away from the color filter CF.

In some embodiments, the display panel is a quantum dots display panel. In a quantum dots display panel, a light source (e.g., a blue light source) is used to excite quantum dots to emit light based on the photoluminescence excitation principle. In some embodiments, the plurality of quantum dots blocks QDB include a first quantum dots block and a second quantum dots block. In one example, the first quantum dots block is configured to convert a light of a third color (e.g., a blue light) into a light of a first color (e.g., a red light). In another example, the second quantum dots block is configured to convert the light of the third color (e.g., a blue light) into a light of a second color (e.g., a green light). The plurality of light scattering blocks LSB do not convert a color of the incident light. Optionally, the plurality of light scattering blocks LSB are configured to scatter the incident light (e.g., a blue light), which emits through a color filter block for image display. The plurality of color filter blocks CFB includes a color filter block of a first color (e.g., a red color filter block) corresponding to the first quantum dots block, a color filter block of a second color (e.g., a green color filter block) corresponding to the second quantum dots block, and a color filter block of a third color (e.g., a blue color filter block) corresponding to a light scattering block.

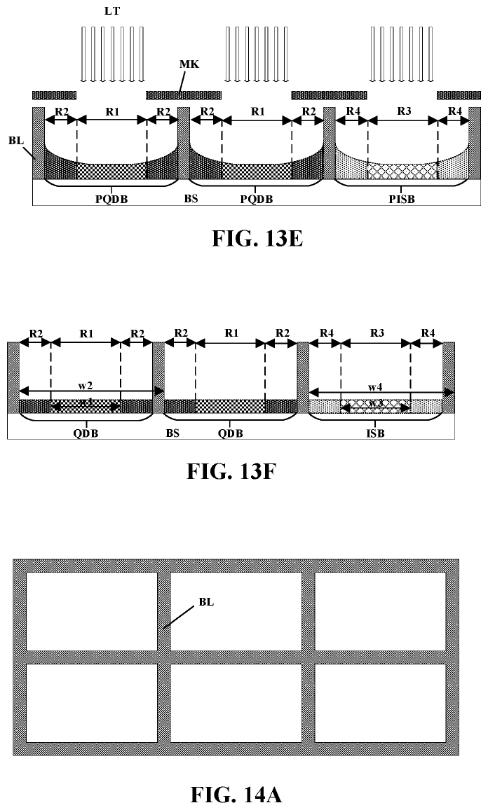

Various appropriate light emitting elements may be implemented in the display panel according to the present disclosure. FIG. 11A is a schematic diagram illustrating the structure of a light emitting element in some embodiments according to the present disclosure. Referring to FIG. 11A, the light emitting element in some embodiments includes an anode AD, a hole transport layer HTL on the anode AD, a first light emitting layer EML1 on a side of the hole transport layer HTL away from the anode AD, an electron transport layer ETL on a side of the first light emitting layer EML1 away from the hole transport layer HTL, and a cathode CD on a side of the electron transport layer ETL away from the first light emitting layer EML1.

In some embodiments, the light emitting element may have a stacked structure. FIG. 11B is a schematic diagram illustrating the structure of a light emitting element in some embodiments according to the present disclosure. Referring to FIG. 11B, the light emitting element in some embodiments includes an anode AD, a hole transport layer HTL on the anode AD, a first light emitting layer EML1 on a side of the hole transport layer HTL away from the anode AD, a first charge generation layer CGL1 on a side of the first light emitting layer EML1 away from the hole transport layer HTL, a second light emitting layer EML2 on a side of the first charge generation layer CGL1 away from the first light emitting layer EML1, an electron transport layer ETL on a side of the second light emitting layer EML2 away from the first charge generation layer CGL1, and a cathode CD on a side of the electron transport layer ETL away from the second light emitting layer EML2.

FIG. 11C is a schematic diagram illustrating the structure of a light emitting element in some embodiments according to the present disclosure. Referring to FIG. 11C, the light emitting element in some embodiments includes an anode AD, a hole transport layer HTL on the anode AD, a first light emitting layer EML1 on a side of the hole transport layer HTL away from the anode AD, a first charge generation layer CGL1 on a side of the first light emitting layer EML1 away from the hole transport layer HTL, a second light emitting layer EML2 on a side of the first charge generation layer CGL1 away from the first light emitting layer EML1, a second charge generation layer CGL2 on a side of the second light emitting layer EML2 away from the first charge generation layer CGL1, a third light emitting layer EML3 on a side of the second charge generation layer CGL2 away from the second light emitting layer EML2, an electron transport layer ETL on a side of the third light emitting layer EML3 away from the second charge generation layer CGL2, and a cathode CD on a side of the electron transport layer ETL away from the third light emitting layer EML3.

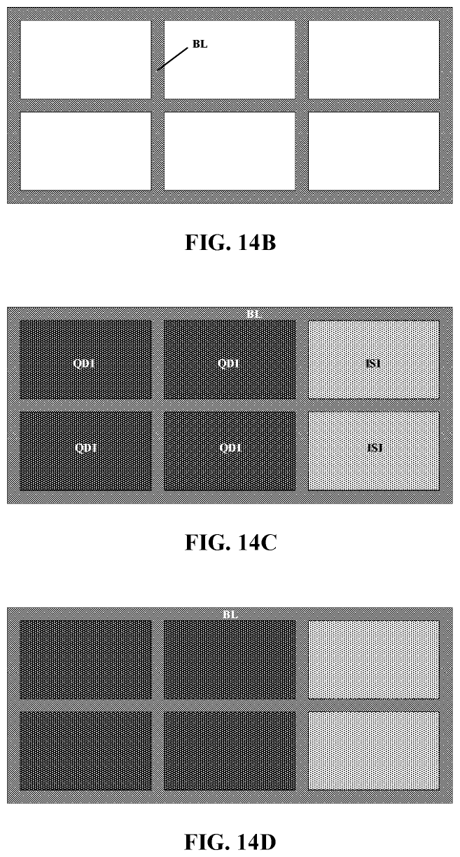

FIG. 12A is a schematic diagram illustrating the structure of a first quantum dots block in some embodiments according to the present disclosure. Referring to FIG. 12A, the first quantum dots block QDB1 is a quantum dots block configured to convert a light of a third color (e.g., a blue light) into a light of a first color (e.g., a red light). In some embodiments, the first quantum dots block QDB1 includes a first matrix MS1, a plurality of first scattering particles SP1 and a plurality of first quantum dots QD1 dispersed in the first matrix MS1. The first matrix MS1 may include a polymer material such as an organic polymer material. Examples of appropriate polymer materials for making the first matrix MS1 include epoxy resins, acrylic resins, polyurethane resins, silicone resins, and silane resins. Examples of appropriate materials for making the plurality of first scattering particles SP1 include TiO₂, ZnO, ZrO₂, Al₂O₃, SiO₂. Examples of appropriate quantum dots materials for making the plurality of first quantum dots QD1 include a quantum dots material of a first color (e.g., a red color). The quantum dots material may include a material selected from a group consisting of CdS, CdSe, ZnSe, InP, PbS, CsPbCl₃, CsPbBr₃, CsPhI₃, CdS/ZnS, CdSe/ZnS, InP/ZnS, PbS/ZnS, CsPbCl₃/ZnS, CsPbBr₃/ZnS, and CsPhI₃/ZnS.

FIG. 12B is a schematic diagram illustrating the structure of a second quantum dots block in some embodiments according to the present disclosure. Referring to FIG. 12B, the second quantum dots block QDB2 is a quantum dots block configured to convert a light of a third color (e.g., a blue light) into a light of a second color (e.g., a green light). In some embodiments, the second quantum dots block QDB2 includes a second matrix MS2, a plurality of second scattering particles SP2 and a plurality of second quantum dots QD2 dispersed in the second matrix MS2. The second matrix MS2 may include a polymer material such as an organic polymer material. Examples of appropriate polymer materials for making the second matrix MS2 include epoxy resins, acrylic resins, polyurethane resins, silicone resins, and silane resins. Examples of appropriate materials for making the plurality of second scattering particles SP2 include TiO₂, ZnO, ZrO₂, Al₂O₃, SiO₂. Examples of appropriate quantum dots materials for making the plurality of second quantum dots QD2 include a quantum dots material of a second color (e.g., a green color). The quantum dots material may include a material selected from a group consisting of CdS, CdSe, ZnSe, InP, PbS, CsPbCl₃, CsPbBr₃, CsPhI₃, CdS/ZnS, CdSe/ZnS, InP/ZnS, PbS/ZnS, CsPbCl₃/ZnS, CsPbBr₃/ZnS, and CsPhI₃/ZnS.

FIG. 12C is a schematic diagram illustrating the structure of a light scattering block in some embodiments according to the present disclosure. Referring to FIG. 12C, the light scattering block LSB in some embodiments includes a third matrix MS3 and a plurality of third scattering particles SP3 dispersed in the third matrix MS3. The third matrix MS3 may include a polymer material such as an organic polymer material. Examples of appropriate polymer materials for making the third matrix MS3 include epoxy resins, acrylic resins, polyurethane resins, silicone resins, and silane resins. Examples of appropriate materials for making the plurality of third scattering particles SP3 include TiO₂, ZnO, ZrO₂, Al₂O₃, SiO₂.

In one example, the first matrix MS1, the second matrix MS2, and the third matrix MS3 includes a same polymer material. In another example, at least two of the first matrix MS1, the second matrix MS2, and the third matrix MS3 includes different polymer materials.

In one example, the first scattering particles SP1, the second scattering particles SP2, and the third scattering particles SP3 includes a same scattering material. In another example, at least two of the first scattering particles SP1, the second scattering particles SP2, and the third scattering particles SP3 includes different scattering materials.

Various appropriate methods may be used for making the quantum dots layer and the light scattering layer. In one example, the quantum dots layer and the light scattering layer may be fabricated by a printing process using inks comprising a quantum dots material or a light scattering material. Typically, the ink-jet printer for printing the inks used an ink-jet head made of a hydrophobic material, and the inks include a highly hydrophilic solvent. The inks are disposed on the substrate, which typically contains a material having a free energy largely different from a free energy of the solvent of the inks. During the printing process, the ink typically climbs up the side walls of the bank layer, resulting in a quantum dots layer or a light scattering layer that has a non-uniform thickness. Typically, the quantum dots layer or the light scattering layer is thicker on edge and thinner in the center (e.g., “coffee-ring effect”). Particularly for the quantum dots layer, the relatively smaller thickness in the center results in a lower light conversion efficiency, adversely affecting the color display of the display panel.

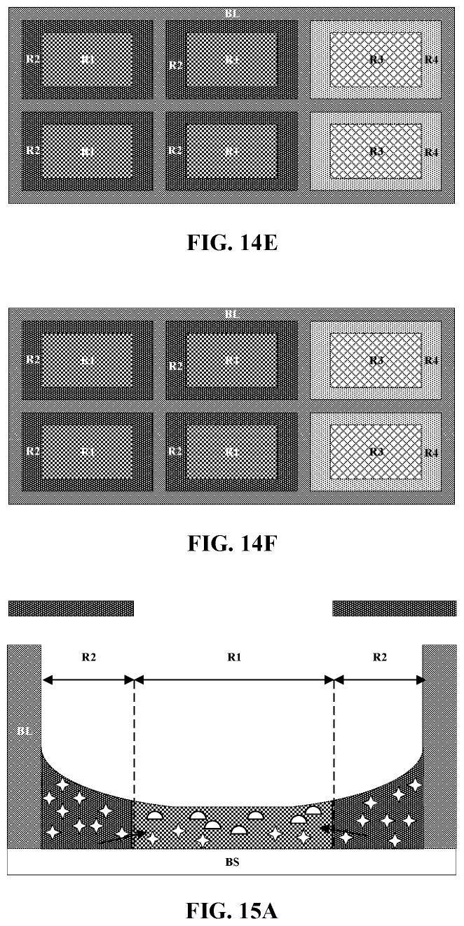

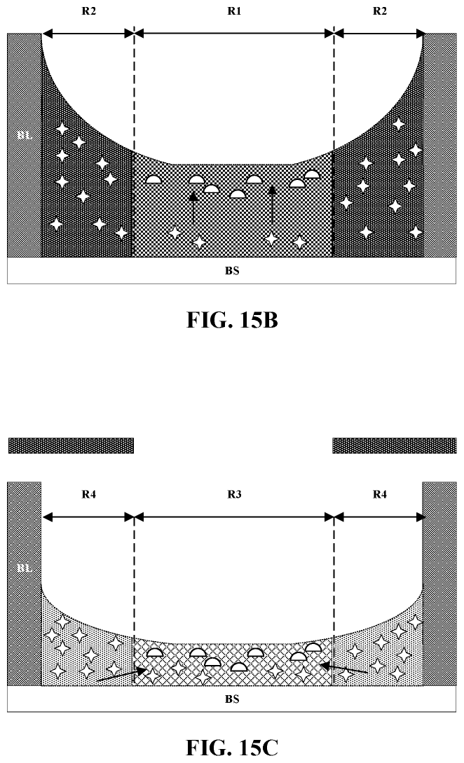

To illustrate the structure of the display substrate of the present disclosure, a process of fabricating the display substrate is briefly described below. FIG. 13A to FIG. 13F illustrate a process of fabricating a display substrate in some embodiments according to the present disclosure. FIG. 14A to FIG. 14F are plan view of a display substrate in each steps of the process depicted in FIG. 13A to FIG. 13F. Referring to FIG. 13A and FIG. 14A, a bank layer BL is formed on a base substrate BS. As shown in FIG. 13A and FIG. 14A, the bank layer BL defines a plurality of apertures. In subsequent steps, a quantum dots layer and a light scattering layer are at least partially in the plurality of apertures defined by the bank layer BL.

Referring to FIG. 13B and FIG. 14B, a printing process is used to print inks into the plurality of apertures. The inks include a quantum dots material ink QD1 for forming the quantum dots layer. Optionally, the inks further include a light scattering material ink ISI for forming the light scattering layer.

Referring to FIG. 13C and FIG. 14C, the quantum dots material ink QD1 is printed into apertures in which quantum dots blocks of the quantum dots layer are formed, and the light scattering material ink ISI is printed into apertures in which light scattering blocks of the light scattering layer are formed. Various appropriate methods may be used to dispose the quantum dots material and the light scattering material into the plurality of apertures. FIG. 13B, FIG. 13C, FIG. 14B, and FIG. 14C depict a printing process. Alternatively, the quantum dots material and the light scattering material may be disposed using a coating process.

Referring to FIG. 13D and FIG. 14D, the inks disposed in the plurality of apertures are precured. As shown in FIG. 13D and FIG. 14D, a plurality of precured quantum dots blocks PQDB and a plurality of precured light scattering blocks PISB are formed in the plurality of apertures. As shown in FIG. 13D, the layers in the plurality of apertures show “coffee-ring effect”, e.g., thicker on edge and thinner in the center.

Referring to FIG. 13E and FIG. 14E, to reduce or eliminate the “coffee-ring effect”, a reaction is initiated in a first region R1 of a respective precured quantum dots block of a plurality of precured quantum dots blocks PQDB whereas the reaction is not initiated in a second region R2. In the example depicted in FIG. 13E and FIG. 14E, the reaction is initiated by light (e.g., UV light). For example, a mask plate MK is used to allow light LT to irradiate on the first region R1, and prevent light LT to irradiate on the second region R2. Various alternative methods of initiating a reaction may be used. Examples of reaction initiation methods include heat initiation, electrical initiation, and initiation by a chemical such as an initiator.

The reaction initiated in the first region R1 converts one or more reactants in the first region R1 into one or more products, thereby reducing a number of the one or more reactants in the first region R1. Because the respective precured quantum dots block is not completely cured, it still allows molecules in the respective precured quantum dots block to move, e.g., from the second region R2 into the first region R1. When the number of the one or more reactants in the first region R1 is reduced, a gradient of the one or more reactants is formed between the first region R1 and the second region R2. In one example, the gradient is a chemical potential gradient. The chemical potential refers to a rate of change of free energy of a thermodynamic system with respect to a change in a number of molecules of the one or more reactants that are supplied to or removed from the thermodynamic system. In another example, the gradient is a concentration gradient of the one or more reactants. Due to the gradient of the one or more reactants between the first region R1 and the second region R2, the one or more reactants diffuses or migrates from the second region R2 to the first region R1 as the one or more reactants are converted into the one or more products in the first region R1.

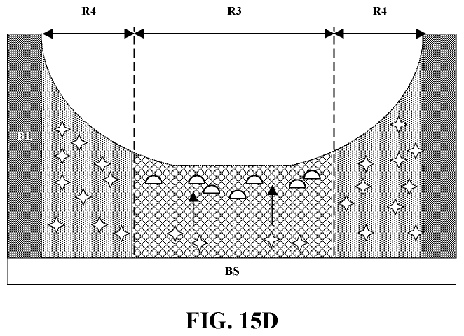

FIG. 15A illustrates migration of one or more reactants from a second region to a first region due to a chemical potential gradient. Referring to FIG. 15A, four-point stars represent the one or more reactants, and half circles represent the one or more products. As shown in FIG. 15A, a reaction is initiated in the first region R1, converting the one or more reactants into the one or more products, thereby creating a gradient (e.g., a chemical potential gradient) between the first region R1 and the second region R2. The reaction is not initiated in the second region R2, for example, light is not irradiated on the second region R2. With the number of the one or more reactants reduced in the first region R1, the one or more reactants (four-point stars) in the second region R2 migrate into the first region R1.

FIG. 15B illustrates migration of one or more reactants from a lower portion of a first region to an upper portion of the first region due to a chemical potential gradient. Referring to FIG. 15B, an upper portion of the first region R1 closer to the incident light is exposed more to the light LT (for example, due to the light funnel effect) as compared to a lower portion of the first region R1 away from the incident light, thus a higher percentage of the one or more reactants in the upper portion is converted into the one or more products as compared to the lower portion, thereby creating a gradient (e.g., a chemical potential gradient) between the upper portion of the first region R1 and the lower portion of the first region R1. With the number of the one or more reactants reduced in the upper portion, the one or more reactants (four-point stars) in the lower portion migrate into the upper portion.

Any one or a combination of the migration of the one or more reactants depicted in FIG. 15A and FIG. 15B results in a “growth” of the first region R1 upward, and/or a shrinkage of the second region R2 downward. For example, due to the chemical potential gradient, a thickness of the first region R1 increases, and/or a thickness of the second region R2 decreases. The end result is a more uniform thickness throughout the respective precured quantum dots block, reducing or eliminating the “coffee-ring effect”. Referring to FIG. 13F and FIG. 14F, the plurality of precured quantum dots blocks are cured to form a plurality of quantum dots blocks QDB. As shown in FIG. 13F and FIG. 14F, a respective quantum dots block of the plurality of quantum dots blocks QDB has a substantially uniform thickness.

In some embodiments, the second region R2 substantially surrounds the first region R1. Optionally, the bank layer substantially surrounds the second region R2, the second region R2 substantially surrounds the first region R1, and the second region R2 spaces apart the first region R1 from the bank layer.

In some embodiments, as discussed further in detail below, the one or more reactants are ligands of a quantum dots in the quantum dots layer. Migration of the one or more reactants drives the quantum dots moving from the second region R2 to the first region R1, and/or moving from the lower portion to the upper portion.

Referring to FIG. 13E and FIG. 14E, to reduce or eliminate the “coffee-ring effect”, a reaction is initiated in a third region R3 of a respective precured light scattering block of a plurality of precured light scattering blocks PISB whereas the reaction is not initiated in a fourth region R4. In the example depicted in FIG. 13E and FIG. 14E, the reaction is initiated by light (e.g., UV light). For example, a mask plate MK is used to allow light LT to irradiate on the third region R3, and prevent light LT to irradiate on the fourth region R4. Various alternative methods of initiating a reaction may be used. Examples of reaction initiation methods include heat initiation, electrical initiation, and initiation by a chemical such as an initiator.

The reaction initiated in the third region R3 converts one or more reactants in the third region R3 into one or more products, thereby reducing a number of the one or more reactants in the third region R3. Because the respective precured light scattering block is not completely cured, it still allows molecules in the respective precured light scattering block to move, e.g., from the fourth region R4 into the third region R3. When the number of the one or more reactants in the third region R3 is reduced, a gradient of the one or more reactants is formed between the third region R3 and the fourth region R4. In one example, the gradient is a chemical potential gradient. In another example, the gradient is a concentration gradient of the one or more reactants. Due to the gradient of the one or more reactants between the third region R3 and the fourth region R4, the one or more reactants diffuses or migrates from the fourth region R4 to the third region R3 as the one or more reactants are converted into the one or more products in the third region R3.

FIG. 15C illustrates migration of one or more reactants from a fourth region to a third region due to a chemical potential gradient. Referring to FIG. 15C, four-point stars represent the one or more reactants, and half circles represent the one or more products. As shown in FIG. 15C, a reaction is initiated in the third region R3, converting the one or more reactants into the one or more products, thereby creating a gradient (e.g., a chemical potential gradient) between the third region R3 and the fourth region R4. The reaction is not initiated in the fourth region R4, for example, light is not irradiated on the fourth region R4. With the number of the one or more reactants reduced in the third region R3, the one or more reactants (four-point stars) in the fourth region R4 migrate into the third region R3.

FIG. 15D illustrates migration of one or more reactants from a lower portion of a third region to an upper portion of the third region due to a chemical potential gradient. Referring to FIG. 15B, an upper portion of the third region R3 closer to the incident light is exposed more to the light LT (for example, due to the light funnel effect) as compared to a lower portion of the third region R3 away from the incident light, thus a higher percentage of the one or more reactants in the upper portion is converted into the one or more products as compared to the lower portion, thereby creating a gradient (e.g., a chemical potential gradient) between the upper portion of the third region R3 and the lower portion of the third region R3. With the number of the one or more reactants reduced in the upper portion, the one or more reactants (four-point stars) in the lower portion migrate into the upper portion.

Any one or a combination of the migration of the one or more reactants depicted in FIG. 15A and FIG. 15B results in a “growth” of the third region R3 upward, and/or a shrinkage of the fourth region R4 downward. For example, due to the chemical potential gradient, a thickness of the third region R3 increases, and/or a thickness of the fourth region R4 decreases. The end result is a more uniform thickness throughout the respective precured light scattering block, reducing or eliminating the “coffee-ring effect”. Referring to FIG. 13F and FIG. 14F, the plurality of precured light scattering blocks are cured to form a plurality of light scattering blocks ISB. As shown in FIG. 13F and FIG. 14F, a respective light scattering block of the plurality of light scattering blocks ISB has a substantially uniform thickness.

In some embodiments, the fourth region R4 substantially surrounds the third region R3. Optionally, the bank layer substantially surrounds the fourth region R4, the fourth region R4 substantially surrounds the third region R3, and the fourth region R4 spaces apart the third region R3 from the bank layer.

Various appropriate reactants, various appropriate products, and various appropriate reactions may be used in the present disclosure. In some embodiments, the reaction is at least one of a dimerization, oligomerization, polymerization, or condensation reaction, or any combination thereof. The one or more reactants could be a monomer in a dimerization reaction, a monomer in an oligomerization reaction, a monomer in a polymerization, a reactant in a condensation reaction, or any combination thereof. Optionally, a reactant may have multiple roles in the reactions, for example, an individual reactant may undergo multiple types of reactions in the fabrication process of the quantum dots layer. In one example, in an individual precured quantum dots block or an individual precured light scattering block, a reactant may undergo at least two different types of reactions such as dimerization, oligomerization, polymerization, or condensation reaction. In another example, in an individual precured quantum dots block or an individual precured light scattering block, a reactant is a reactant in a dimerization reaction, and at the same time a reactant in a Diels-Alder reaction.

In some embodiments, the reaction is one that initiated by a non-chemical initiator. Examples of non-chemical initiators include light, heat, pressure, an electrical signal, microwave, and ultrasound. Accordingly, in some embodiments, the quantum dots layer or the light scattering layer is absent of any chemical initiator (e.g., a photo-initiator molecule) or reaction product thereof.

In some embodiments, the display substrate includes a quantum dots layer. The quantum dots layer includes a plurality of quantum dots blocks QDB respectively in a plurality of first apertures. In some embodiments, a respective quantum dots block of the plurality of quantum dots blocks includes a first region R1 and a second region R2.

In some embodiments, a ratio of a respective reactant of the one or more reactants to a respective product of the respective reactant produced by a respective reaction in the second region is greater than a ratio of the respective reactant of the one or more reactants to a respective product of the respective reactant produced by a respective reaction in the first region. Optionally, the ratio of the respective reactant of the one or more reactants to the respective product of the respective reactant produced by the respective reaction in the second region is greater than the ratio of the respective reactant of the one or more reactants to the respective product of the respective reactant produced by a respective reaction in the first region by at least 1%, e.g., by at least 2%, by at least 3%, by at least 4%, by at least 5%, by at least 10%, by at least 15%, by at least 20%, by at least 25%, by at least 30%, by at least 35%, by at least 40%, by at least 45%, by at least 50%, by at least 55%, by at least 60%, by at least 65%, by at least 70%, by at least 75%, by at least 80%, by at least 85%, by at least 90%, by at least 95%, by at least 100%, by at least 150%, by at least 200%, by at least 300%, by at least 400%, or by at least 500%.

In some embodiments, the ratio of the respective reactant of the one or more reactants to the respective product of the respective reactant produced by a respective reaction in the first region has a gradient distribution. A ratio of the respective reactant of the one or more reactants to the respective product of the respective reactant produced by a respective reaction in a first sub-region of the first region is greater than a ratio of the respective reactant of the one or more reactants to the respective product of the respective reactant produced by a respective reaction in a second sub-region of the first region. The second sub-region (e.g., a central sub-region of the first region) is on a side of the first sub-region (e.g., a surrounding sub-region) away from the second region.

In some embodiments, a concentration of the respective product of the respective reactant produced by the respective reaction in the first region is greater than a concentration of the respective product of the respective reactant produced by the respective reaction in the second region. Optionally, the concentration of the respective product of the respective reactant produced by the respective reaction in the first region is greater than the concentration of the respective product of the respective reactant produced by the respective reaction in the second region by at least 1%, e.g., by at least 2%, by at least 3%, by at least 4%, by at least 5%, by at least 10%, by at least 15%, by at least 20%, by at least 25%, by at least 30%, by at least 35%, by at least 40%, by at least 45%, by at least 50%, by at least 55%, by at least 60%, by at least 65%, by at least 70%, by at least 75%, by at least 80%, by at least 85%, by at least 90%, by at least 95%, by at least 100%, by at least 150%, by at least 200%, by at least 300%, by at least 400%, or by at least 500%.

In some embodiments, the concentration of the respective product of the respective reactant produced by the respective reaction in the first region has a gradient distribution. A concentration of the respective product of the respective reactant produced by the respective reaction in a second sub-region of the first region is greater than a concentration of the respective product of the respective reactant produced by the respective reaction in a first sub-region of the first region. The second sub-region (e.g., a central sub-region of the first region) is on a side of the first sub-region (e.g., a surrounding sub-region) away from the second region.

In some embodiments, the concentration of the respective reactant of the respective reaction in the first region has a gradient distribution. A concentration of the respective reactant of the respective reaction in a first sub-region of the first region is greater than a concentration of the respective reactant of the respective reaction in a second sub-region of the first region. The second sub-region (e.g., a central sub-region of the first region) is on a side of the first sub-region (e.g., a surrounding sub-region) away from the second region.

In some embodiments, the respective reactant comprises a ligand chelated to a quantum dots.

In some embodiments, referring to FIG. 13F, in a cross-section perpendicular to a surface of the base substrate and intersecting multiple adjacent quantum dots blocks of the plurality of quantum dots blocks QDB (e.g., a cross-section as shown in FIG. 13F), the first region R1 has a first width w1, and the first region R1 and the second region R2 in combination have a second width w2. In some embodiments, a ratio of the first width w1 to the second width w2 is greater than 1:10, e.g., greater than 2:10, greater than 3:10, greater than 4:10, greater than 5:10, greater than 6:10, greater than 7:10, greater than 8:10, greater than 9:10. In some embodiments, the ratio of the first width w1 to the second width w2 is less than 10:1, e.g., less than 9:1, less than 8:1, less than 7:1, less than 6:1, less than 5:1, less than 4:1, less than 3:1, less than 2:1, less than 1:1, less than 1:2, less than 1:3, less than 1:4, less than 1:5, less than 1:6, less than 1:7, less than 1:8, less than 1:9, or less than 1:10.

In some embodiments, referring to FIG. 13F, the respective quantum dots block of the plurality of quantum dots blocks QDB has a substantially uniform average thickness throughout the first region R1 and the second region R2. In some embodiments, an average thickness of the first region R1 is substantially the same as an average thickness of the second region R2. Optionally, a difference between the average thickness of the first region R1 and the average thickness of the second region R2 is equal to or less than 15 nm, e.g., equal to or less than 10 nm, equal to or less than 5 nm, equal to or less than 3 nm, equal to or less than 2 nm, or equal to or less than 1 nm. In one example, the difference between the average thickness of the first region R1 and the average thickness of the second region R2 is equal to or less than 5 nm.

In some embodiments, the display substrate further includes a light scattering layer. The light scattering layer includes a plurality of light scattering blocks respectively in a plurality of second apertures. In some embodiments, a respective light scattering block of the plurality of light scattering blocks includes a third region R3 and a fourth region R4.

In some embodiments, a ratio of a respective reactant of the one or more reactants to a respective product of the respective reactant produced by a respective reaction in the fourth region is greater than a ratio of the respective reactant of the one or more reactants to a respective product of the respective reactant produced by a respective reaction in the third region. Optionally, the ratio of the respective reactant of the one or more reactants to the respective product of the respective reactant produced by the respective reaction in the fourth region is greater than the ratio of the respective reactant of the one or more reactants to a respective product of the respective reactant produced by a respective reaction in the third region by at least 1%, e.g., by at least 2%, by at least 3%, by at least 4%, by at least 5%, by at least 10%, by at least 15%, by at least 20%, by at least 25%, by at least 30%, by at least 35%, by at least 40%, by at least 45%, by at least 50%, by at least 55%, by at least 60%, by at least 65%, by at least 70%, by at least 75%, by at least 80%, by at least 85%, by at least 90%, by at least 95%, by at least 100%, by at least 150%, by at least 200%, by at least 300%, by at least 400%, or by at least 500%.

In some embodiments, the ratio of the respective reactant of the one or more reactants to the respective product of the respective reactant produced by a respective reaction in the third region has a gradient distribution. A ratio of the respective reactant of the one or more reactants to the respective product of the respective reactant produced by a respective reaction in a third sub-region of the third region is greater than a ratio of the respective reactant of the one or more reactants to the respective product of the respective reactant produced by a respective reaction in a fourth sub-region of the third region. The fourth sub-region (e.g., a central sub-region of the third region) is on a side of the third sub-region (e.g., a surrounding sub-region) away from the fourth region.

In some embodiments, a concentration of the respective product of the respective reactant produced by the respective reaction in the third region is greater than a concentration of the respective product of the respective reactant produced by the respective reaction in the fourth region. Optionally, the concentration of the respective product of the respective reactant produced by the respective reaction in the third region is greater than a concentration of the respective product of the respective reactant produced by the respective reaction in the fourth region by at least 1%, e.g., by at least 2%, by at least 3%, by at least 4%, by at least 5%, by at least 10%, by at least 15%, by at least 20%, by at least 25%, by at least 30%, by at least 35%, by at least 40%, by at least 45%, by at least 50%, by at least 55%, by at least 60%, by at least 65%, by at least 70%, by at least 75%, by at least 80%, by at least 85%, by at least 90%, by at least 95%, by at least 100%, by at least 150%, by at least 200%, by at least 300%, by at least 400%, or by at least 500%.

In some embodiments, the concentration of the respective product of the respective reactant produced by the respective reaction in the third region has a gradient distribution. A concentration of the respective product of the respective reactant produced by the respective reaction in a fourth sub-region of the third region is greater than a concentration of the respective product of the respective reactant produced by the respective reaction in a third sub-region of the third region. The fourth sub-region (e.g., a central sub-region of the third region) is on a side of the third sub-region (e.g., a surrounding sub-region) away from the fourth region.

In some embodiments, the concentration of the respective reactant of the respective reaction in the third region has a gradient distribution. A concentration of the respective reactant of the respective reaction in a third sub-region of the third region is greater than a concentration of the respective reactant of the respective reaction in a fourth sub-region of the third region. The fourth sub-region (e.g., a central sub-region of the third region) is on a side of the third sub-region (e.g., a surrounding sub-region) away from the fourth region.

In some embodiments, referring to FIG. 13F, in a cross-section perpendicular to a surface of the base substrate and intersecting multiple adjacent light scattering blocks of the plurality of light scattering blocks ISB (e.g., a cross-section as shown in FIG. 13F), the third region R3 has a third width w3, and the third region R3 and the fourth region R4 in combination have a fourth width w4. In some embodiments, a ratio of the third width w3 to the fourth width w4 is greater than 1:10, e.g., greater than 2:10, greater than 3:10, greater than 4:10, greater than 5:10, greater than 6:10, greater than 7:10, greater than 8:10, greater than 9:10. In some embodiments, the ratio of the third width w3 to the fourth width w4 is less than 10:1, e.g., less than 9:1, less than 8:1, less than 7:1, less than 6:1, less than 5:1, less than 4:1, less than 3:1, less than 2:1, less than 1:1, less than 1:2, less than 1:3, less than 1:4, less than 1:5, less than 1:6, less than 1:7, less than 1:8, less than 1:9, or less than 1:10.

In some embodiments, referring to FIG. 13F, the respective light scattering block of the plurality of light scattering blocks ISB has a substantially uniform average thickness throughout the third region R3 and the fourth region R4. In some embodiments, an average thickness of the third region R3 is substantially the same as an average thickness of the fourth region R4.

In some embodiments, the one or more reactants includes a dienophile functional group. Examples of dienophile functional groups include ethylene group, acetylene group, and nitrile group.

In some embodiments, the one or more reactants includes a bis dienophile functional group. Examples of bis dienophile functional group includes bismaleimide functional group. Optionally, the one or more reactants having a bis dienophile functional group is selected from the group consisting of:

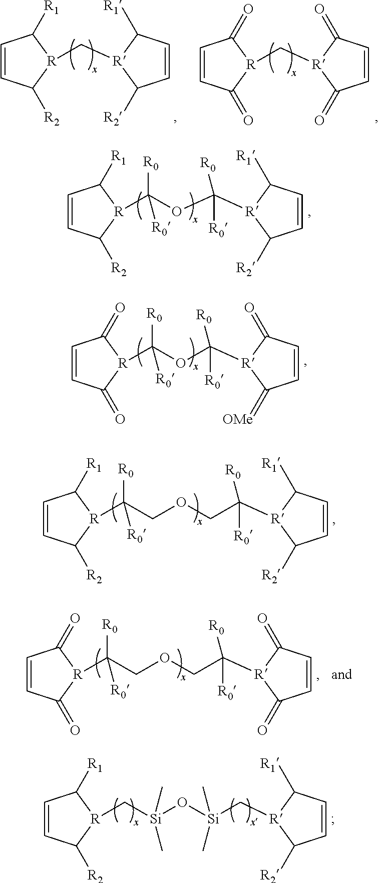

wherein R is nitrogen or —CH; R′ is nitrogen or —CH; R₀, R₀′, R₁, R₁′, R₂, R₂′ are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures); and x and x′ are independently a positive integer equal to or greater than 2.

Optionally, R₀ is hydrogen or a methyl group. Optionally, R₀′ is hydrogen or a methyl group. Optionally, R₁ is selected from the group consisting of hydrogen, a methyl group, and a methylene group. Optionally, R₁′ is selected from the group consisting of hydrogen, a methyl group, and a methylene group. Optionally, R₂ is selected from the group consisting of hydrogen, a methyl group, and a methylene group. Optionally, R₂′ is selected from the group consisting of hydrogen, a methyl group, and a methylene group. Optionally, x is an integer in a range of 2 to 10. Optionally, x′ is an integer in a range of 2 to 10.

Depending on the solvent used in the inks, the linker group between two dienophile functional groups in the bis dienophile functional group can be varied. For example, when the linker group includes an alkyl group, a greater x would result in a higher solubility of the reactant in a non-polar solvent of the ink. When the linker group includes an ester bond, a greater x would result in a higher solubility of the reactant in a polar solvent of the ink.

In one example, the one or more reactants include:

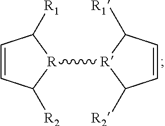

Optionally, a linker group between two R groups in the formula includes 2 to 10 carbon atoms.

In one example, the one or more reactants include bismaleimide. Optionally, bismaleimide has a formula of:

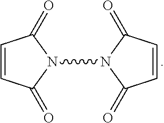 [SMILES: O=C1C=CC(=O)N1N1C(=O)C=CC1=O]

Optionally, a linker group between two nitrogen atoms in the formula includes 2 to 10 carbon atoms.

In some embodiments, the one or more reactants having a conjugated diene functional group may be represented by:
wherein a respective reactant of the one or more reactants includes a main chain MC and a conjugated diene functional group Rₓ is covalently bonded to the main chain MC. Optionally, the main chain MC includes at least one carbon atom, e.g., at least 5 carbon atoms, at least 10 carbon atoms, at least 15 carbon atoms, at least 20 carbon atoms, at least 25 carbon atoms, at least 30 carbon atoms, at least 35 carbon atoms, at least 40 carbon atoms, at least 45 carbon atoms, at least 50 carbon atoms, at least 55 carbon atoms, at least 60 carbon atoms, at least 65 carbon atoms, at least 70 carbon atoms, at least 75 carbon atoms, at least 80 carbon atoms, at least 85 carbon atoms, at least 90 carbon atoms, at least 95 carbon atoms, or at least 100 carbon atoms. Optionally, the main chain MC includes less than 100 carbon atoms, e.g., less than 95 carbon atoms, less than 90 carbon atoms, less than 85 carbon atoms, less than 80 carbon atoms, less than 75 carbon atoms, less than 70 carbon atoms, less than 65 carbon atoms, less than 60 carbon atoms, less than 55 carbon atoms, less than 50 carbon atoms, less than 45 carbon atoms, less than 40 carbon atoms, less than 35 carbon atoms, less than 30 carbon atoms, less than 25 carbon atoms, less than 20 carbon atoms, less than 15 carbon atoms, less than 10 carbon atoms, or less than 5 carbon atoms.

In some embodiments, the one or more reactants having a conjugated diene functional group is selected from the group consisting of:

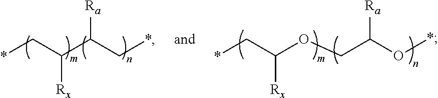

wherein Rₓ stands for the conjugated diene functional group, the one or more reactants further includes a main chain, the conjugated diene functional group Rₓ is connected to the main chain.

Optionally, m is a positive integer, n is zero or a positive integer, 10≤ (m+n)≤100. The inventors of the present disclosure discover that, a criticality is provided having the length of the main chain in this range, and an unexpected results can be achieved. By having the length of the main chain in this range, the reaction product of the reactant is in a range of molecular weight that results in a good solubility in the precured quantum dots block or the precured light scattering block. The reaction product is well dispersed in the precured quantum dots block or the light scattering block, without adversely affecting physical and chemical properties of the precured quantum dots block or the precured light scattering block. A substantially uniform thickness can be achieved in the quantum dots block or the light scattering block.

Optionally, Rₐ is hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures). The inventors of the present disclosure discover that, by varying the composition of the Ra group, solubility of the reactant and its product in the precured quantum dots block or the precured light scattering block can be adjusted. Depending on the solvent used in the inks, the composition of the Rₐ group can be varied. Moreover, mechanical strength of the quantum dots block or the light scattering block can be adjusted by selecting an appropriate composition of the Rₐ group.

Optionally, Rₐ is selected from the group consisting of hydrogen, substituted or unsubstituted C₁ to C₂₀ alkyl, or substituted or unsubstituted phenyl.

Optionally, Rₓ is selected from the group consisting of:

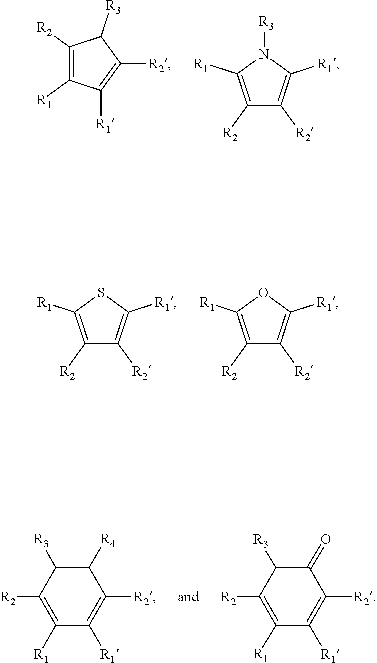

Optionally, one of R₁, R₁′, R₂, R₂′, R₃, and R₄ is connected to the main chain of the reactant, the one of R₁, R₁′, R₂, R₂′, R₃, and R₄ connected to the main chain of the reactant is substituted or unsubstituted alkylene (e.g. substituted or unsubstituted C₁ to C₂₀ alkylene), substituted or unsubstituted alkylene comprising an amide group, substituted or unsubstituted alkylene comprising an ester group, substituted or unsubstituted alkylene comprising a nitrogenous five-membered heterocycle, substituted or unsubstituted heteroalkylene (e.g. substituted or unsubstituted 2 to 20 membered heteroalkylene), substituted or unsubstituted cycloalkylene (e.g. C₃ to C₁₄ cycloalkylene including fused ring structures), substituted or unsubstituted heterocycloalkylene (e.g. 3 to 14 membered heterocycloalkyl including fused ring structures), substituted or unsubstituted arylene (e.g. a C₆ to C₁₄ aryl including fused ring structures), or substituted or unsubstituted heteroarylene (e.g. 5 to 14 membered heteroaryl including fused rings structures). The other five of R₁, R₁′, R₂, R₂′, R₃, and R₄ that are not connected to the main chain of the reactant are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures).

Optionally, the one of R₁, R₁′, R₂, R₂′, R₃, and R₄ connected to the main chain of the reactant is substituted or unsubstituted alkylene, substituted or unsubstituted alkylene comprising an amide group, substituted or unsubstituted alkylene comprising an ester group, substituted or unsubstituted alkylene comprising a nitrogenous five-membered heterocycle.

Optionally, the one of R₁, R₁′, R₂, R₂′, R₃, and R₄ connected to the main chain of the reactant is selected from the group consisting of a methylene group, an ethylene group, a propylene group, a butylene group, a pentylene group, and a hexatylene group. Examples of one of R₁, R₁′, R₂, R₂′, R₃, and R₄ connected to the main chain of the reactant include

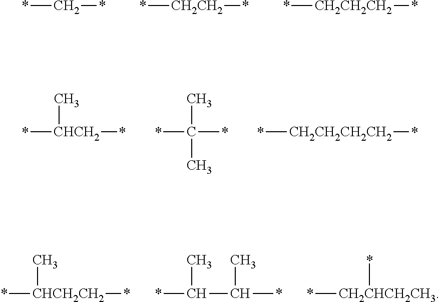

Optionally, the one of R₁, R₁′, R₂, R₂′, R₃, and R₄ connected to the main chain of the reactant is selected from the group consisting of:

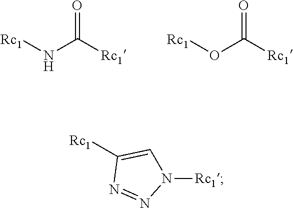

wherein Rc₁ and Rc₁′ are independently substituted or unsubstituted alkylene. Optionally, Rc₁ is selected from the group consisting of a methylene group, an ethylene group, a propylene group, a butylene group, a pentylene group, and a hexatylene group. Optionally, Rc₁′ is selected from the group consisting of a methylene group, an ethylene group, a propylene group, a butylene group, a pentylene group, and a hexatylene group.

Optionally, the other five of R₁, R₁′, R₂, R₂′, R₃, and R₄ that are not connected to the main chain of the reactant are independently hydrogen, a methyl group, a methylene group, an ethyl group, and an ethylidene group.

In some embodiments, the reaction is a dimerization reaction. Optionally, the dimerization reaction is a dimerization reaction between two reactant molecules having a bis dienophile functional group. An example of the dimerization reaction is provided below:

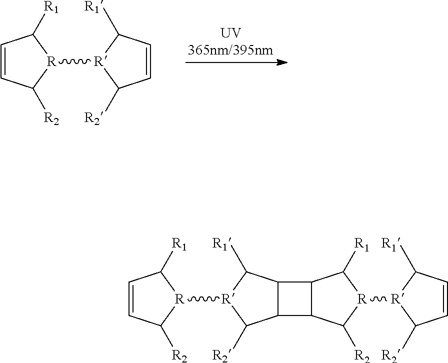

In some embodiments, the one or more products of the one or more reactants include a dimerization product of two reactant molecules having a bis dienophile functional group.

In some embodiments, the reaction is a Diels-Alder reaction. Optionally the Diels-Alder reaction is a reaction between a reactant having a bis dienophile functional group and a reactant having a conjugated diene functional group. An example of the Diels-Alder reaction is provided below:

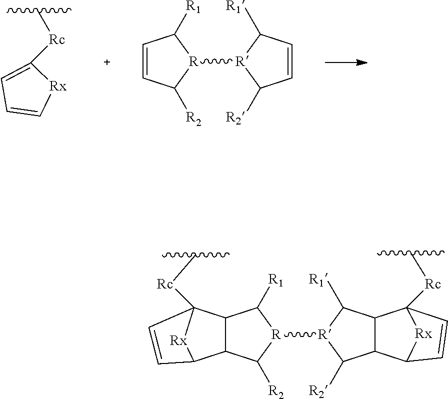

In some embodiments, the one or more products of the one or more reactants include a Diels-Alder reaction product of a reactant having a bis dienophile functional group and a reactant having a conjugated diene functional group.

In related display substrates, numerous parameters have to be adjusted and numerous factors have to be considered in order to reduce “coffee-ring effect” during deposition of the quantum dots ink solution or the light scattering ink solution. For example, parameters and factors that affect the quality of the quantum dots layer or the light scattering layer include surface properties of the substrate for depositing the ink solution, surface treatment of the bank layer, microstructure design on the surface of the bank layer, solvent wettability of the ink solution, speed of spin coating when spin coating is utilized for deposition of the ink solution, ink solution deposition speed, droplet volume in depositing the ink solution when inkjet printing is utilized for deposition of the ink solution, temperature of a hot plate or a cold plate in the vacuum drying cell, air extraction rate and pressure during vacuuming. To improve layer homogeneity, all these parameters and factors need to be considered and fine-tuned, which require a large number of experiments and adjustments to obtain the optimal combination of parameters to achieve an acceptable result. This process in fabricating the related display substrates is time consuming and labor intensive. An optimized combination of parameters suffers from poor stability and reproducibility. Once the process is performed, any defects in the quantum dots layer or the light scattering layer cannot be easily further optimized or repaired.

The present disclosure obviates this time consuming and labor intensive yet sometimes ineffective process in fabricating the display substrate. The inventors of the present disclosure discover that, surprisingly and unexpectedly, by creating a chemical potential gradient between the first region and the second region, or between the third region and the fourth region, a substantially uniform and homogenous quantum dots block or light scattering block can be fabricated without the need of optimizing and fine-tuning numerous parameters and factors.

In some embodiments, the one or more reactants in the ink solution includes a mixture of a reactant having a bis dienophile functional group and a reactant having a conjugated diene functional group. In the ink solution, a weight ratio of the reactant having a bis dienophile functional group to the reactant having a conjugated diene functional group is in a range of 1:1 to 9:1, e.g., 1:1 to 2:1, 2:1 to 3:1, 3:1 to 4:1, 4:1 to 5:1, 5:1 to 6:1, 6:1 to 7:1, 7:1 to 8:1, or 8:1 to 9:1. Optionally, the weight ratio of the reactant having a bis dienophile functional group to the reactant having a conjugated diene functional group is in a range of 3:2 to 4:1.

In some embodiments, a weight ratio of quantum dots to a combination of the reactant having a bis dienophile functional group to the reactant having a conjugated diene functional group in the ink solution is in a range of 10:1 to 10:3.5, e.g., 10:1 to 10:1.5, 10:1.5 to 10:2.0, 10:2.0 to 10:2.5, 10:2.5 to 10:3.0, or 10:3.0 to 10:3.5. The inventors of the present disclosure discover that, a criticality is provided having the weight ratio of quantum dots to the combination of the reactant having a bis dienophile functional group to the reactant having a conjugated diene functional group in the ink solution in this range. By having the weight ratio in this range, electrical properties of the quantum dots are not adversely affected by the presence of the one or more reactants. For example, by having the weight ratio in this range, the presence of the one or more reactants does not present difficulty in carrier injection, and does not cause a lower device efficiency.

In some embodiments, the one or more reactants are not conjugated or chelated to the quantum dots.

In some embodiments, at least one of the one or more reactants is conjugated or chelated to the quantum dots. Optionally, the at least one of the one or more reactants is a ligand chelated to the quantum dots. The inventors of the present disclosure discover that a synergistic effect can be achieved by coupling the one or more reactants to the quantum dots. Driven by the chemical potential gradient, the one or more reactants diffuses or migrates from the second region R2 to the first region R1 as the one or more reactants are converted into the one or more products in the first region R1. The quantum dots, chelated to the one or more reactants, also diffuses or migrates from the second region R2 to the first region R1. Not only a substantially uniform thickness of the quantum dots block can be achieved, but also the quantum dots may be evenly distributed throughout the first region R1 and the second region R2, achieving a substantially uniform luminance throughout the first region R1 and the second region R2.

In some embodiments, the reactant having a bis dienophile functional group comprises a bis dienophile functional group and a quantum dots chelating group. Optionally, the reactant having a bis dienophile functional group is chelated to the quantum dots. Optionally, the reactant having a bis dienophile functional group is represented by:
wherein QD stands for a quantum dots, CG stands for a quantum dots chelating group, and BDG stands for a bis dienophile functional group. Examples of quantum dots chelating groups include a carboxyl group (e.g., R—COOH), an amine group (e.g., R-NH2,R2-NH, R3-N), an amino group, a thiol group (e.g., R—SH), an ester group (e.g., R—COOR), a hydroxyl group (e.g., R—OH), a phosphorus group, a phosphine group (e.g., R3-P), a phosphinyloxy group (e.g., R3-PO), and a hydroxyphosphinyloxy group (e.g., RPO(OH)2 and R2POOH).

Optionally, the one or more reactants having a bis dienophile functional group is selected from the group consisting of:

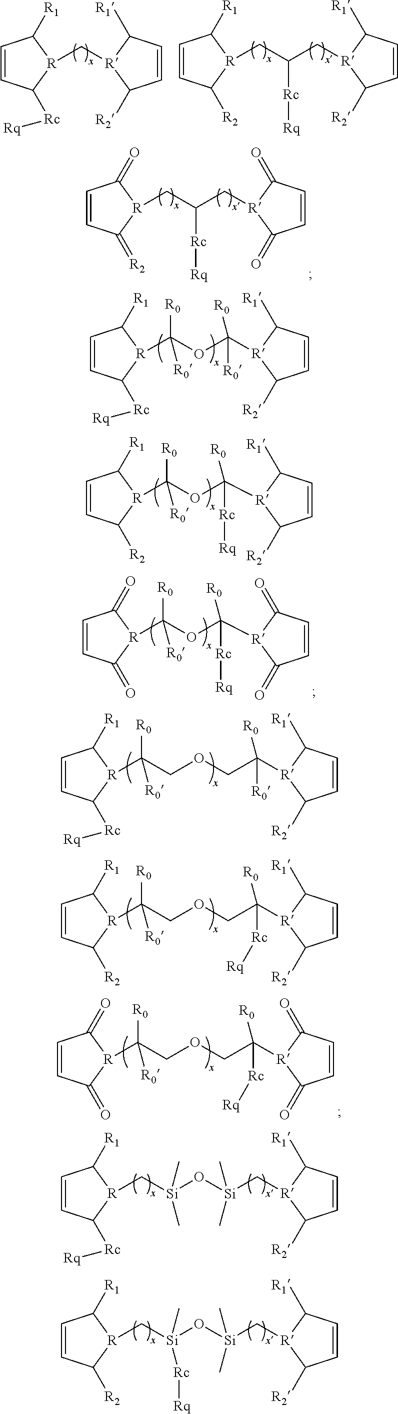

wherein R is nitrogen or —CH; R′ is nitrogen or —CH; R₀, R₀′, R₁, R₁′, R₂, R₂′ are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures); and x and x′ are independently a positive integer equal to or greater than 2;
wherein R_{c} is substituted or unsubstituted alkylene (e.g. substituted or unsubstituted C₁ to C₂₀ alkylene), substituted or unsubstituted alkylene comprising an amide group, substituted or unsubstituted alkylene comprising an ester group, substituted or unsubstituted alkylene comprising a nitrogenous five-membered heterocycle, substituted or unsubstituted heteroalkylene (e.g. substituted or unsubstituted 2 to 20 membered heteroalkylene), substituted or unsubstituted cycloalkylene (e.g. C₃ to C₁₄ cycloalkylene including fused ring structures), substituted or unsubstituted heterocycloalkylene (e.g. 3 to 14 membered heterocycloalkyl including fused ring structures), substituted or unsubstituted arylene (e.g. a C₆ to C₁₄ aryl including fused ring structures), or substituted or unsubstituted heteroarylene (e.g. 5 to 14 membered heteroaryl including fused rings structures); and
wherein R_{q} stands for a quantum dots chelating group.
Optionally, R₀ is hydrogen or a methyl group. Optionally, R₀′ is hydrogen or a methyl group. Optionally, R₁ is selected from the group consisting of hydrogen, a methyl group, and a methylene group. Optionally, R₁′ is selected from the group consisting of hydrogen, a methyl group, and a methylene group. Optionally, R₂ is selected from the group consisting of hydrogen, a methyl group, and a methylene group. Optionally, R₂′ is selected from the group consisting of hydrogen, a methyl group, and a methylene group. Optionally, x is an integer in a range of 2 to 16. Optionally, x′ is an integer in a range of 2 to 16. In one example, (x+x′) is an integer in a range of 2 to 16.

Optionally, R_{q} is selected from the group consisting of a carboxyl group (e.g., R-COOH), an amine group (e.g., R-NH2, R2-NH, R3-N), an amino group, a thiol group (e.g., R-SH), an ester group (e.g., R-COOR), a hydroxyl group (e.g., R—OH), a phosphorus group, a phosphine group (e.g., R3-P), a phosphinyloxy group (e.g., R3-PO), and a hydroxyphosphinyloxy group (e.g., RPO(OH)2 and R2POOH).

Optionally, R_{c} is selected from the group consisting of substituted or unsubstituted C₆ to C₁₈ alkylene,

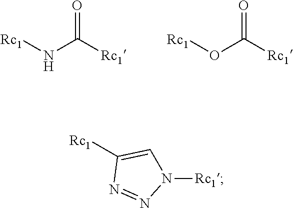

wherein Rc₁ and Rc₁′ are independently substituted or unsubstituted alkyl. Optionally, Rc₁ and Rc₁′ are independently substituted or unsubstituted C₆ to C₁₈ alkyl.

Various appropriate methods may be utilized to chelate the reactant to the quantum dots. In some embodiments, the chelating may be achieved by ligand exchange. In one specific example, a first quantum dots solution comprising a plurality of quantum dots are provided. Typically, the quantum dots in the first quantum dots solution is dissolved in organic solvents such as hexane, heptane, and octane. In the first quantum dots solution, ligands such as oleic acid, oleylamine, octylamine, thiol, trioctyl phosphine oxide are chelated to the quantum dots. The method includes drying the first quantum dots solution to remove the solvent therein, e.g., by blow-dried, drained, or spin-dried. Subsequent to the drying, a new solvent (e.g., toluene, xylene, chloroform, dichloromethane, or a mixture thereof) is added to dissolve the quantum dots in a concentration of 5 mg/ml to 30 mg/ml. Subsequent to the dissolving step, the reactant having the quantum dots chelating group and the bis dienophile functional group is added to the solution, and the solution is stirred for 4 to 8 hours at room temperature to allow chelating between the reactant and the quantum dots. Subsequently, the solution is added into methanol to precipitate the quantum dots, thereby obtaining the reactant chelated to the quantum dots.

In some embodiments, the one or more reactants include a first reactant having a bis dienophile functional group, and a quantum dots chelating group chelated to a quantum dots. Optionally, the one or more reactants further include a second reactant having a conjugated diene functional group. Optionally, the second reactant is not chelated to a quantum dots, and does not include a quantum dots chelating group.

In some embodiments, a reaction product (e.g., a dimerization product or a Diels-Alder reaction product) of the first reactant is chelated to a quantum dots. In some embodiments, a reaction product (e.g., a Diels-Alder reaction product) of the second reactant is chelated to a quantum dots because the Diels-Alder reaction is a reaction between the first reactant and the second reactant.

In some embodiments, the reaction is a dimerization reaction. Optionally, the dimerization reaction is a dimerization reaction between two reactant molecules having a bis dienophile functional group. An example of the dimerization reaction is provided below:

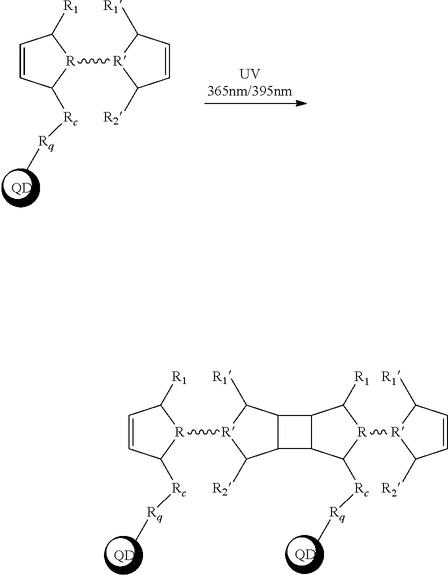

In some embodiments, the one or more products of the one or more reactants include a dimerization product of two reactant molecules having a bis dienophile functional group.

In some embodiments, the reaction is a Diels-Alder reaction. Optionally the Diels-Alder reaction is a reaction between a reactant having a bis dienophile functional group and a reactant having a conjugated diene functional group. An example of the Diels-Alder reaction is provided below:

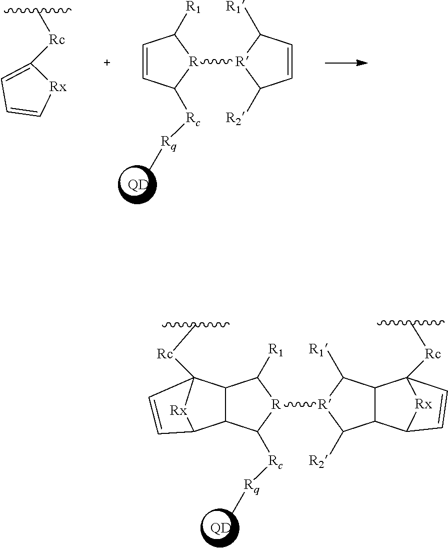

In some embodiments, the one or more products of the one or more reactants include a Diels-Alder reaction product of a reactant having a bis dienophile functional group and a reactant having a conjugated diene functional group.

In some embodiments, the reactant having a conjugated diene functional group comprises a conjugated diene functional group and a quantum dots chelating group. Optionally, the reactant having the conjugated diene functional group is chelated to the quantum dots. Optionally, the reactant having the conjugated diene functional group is represented by:
wherein QD stands for a quantum dots, CG stands for a quantum dots chelating group, and CDG stands for a conjugated diene functional group. Examples of quantum dots chelating groups include a carboxyl group (e.g., R—COOH), an amine group (e.g., R-NH2, R2-NH, R3-N), an amino group, a thiol group (e.g., R-SH), an ester group (e.g., R-COOR), a hydroxyl group (e.g., R—OH), a phosphorus group, a phosphine group (e.g., R3-P), a phosphinyloxy group (e.g., R3-PO), and a hydroxyphosphinyloxy group (e.g., RPO(OH)2 and R2POOH).

In some embodiments, the one or more reactants having a conjugated diene functional group may be represented by:
wherein R_{q} stands for a quantum dots chelating group; a respective reactant of the one or more reactants includes a main chain MC and a conjugated diene functional group Rₓ is covalently bonded to the main chain MC. Optionally, the main chain MC includes at least one carbon atom, e.g., at least 5 carbon atoms, at least 10 carbon atoms, at least 15 carbon atoms, at least 20 carbon atoms, at least 25 carbon atoms, at least 30 carbon atoms, at least 35 carbon atoms, at least 40 carbon atoms, at least 45 carbon atoms, at least 50 carbon atoms, at least 55 carbon atoms, at least 60 carbon atoms, at least 65 carbon atoms, at least 70 carbon atoms, at least 75 carbon atoms, at least 80 carbon atoms, at least 85 carbon atoms, at least 90 carbon atoms, at least 95 carbon atoms, or at least 100 carbon atoms. Optionally, the main chain MC includes less than 100 carbon atoms, e.g., less than 95 carbon atoms, less than 90 carbon atoms, less than 85 carbon atoms, less than 80 carbon atoms, less than 75 carbon atoms, less than 70 carbon atoms, less than 65 carbon atoms, less than 60 carbon atoms, less than 55 carbon atoms, less than 50 carbon atoms, less than 45 carbon atoms, less than 40 carbon atoms, less than 35 carbon atoms, less than 30 carbon atoms, less than 25 carbon atoms, less than 20 carbon atoms, less than 15 carbon atoms, less than 10 carbon atoms, or less than 5 carbon atoms.

In some embodiments, the one or more reactants having a conjugated diene functional group is selected from the group consisting of:

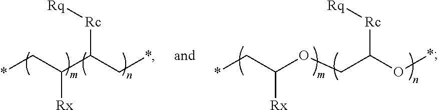

wherein Rₓ stands for the conjugated diene functional group, the one or more reactants further includes a main chain, the conjugated diene functional group Rₓ is connected to the main chain; R_{q} stands for a quantum dots chelating group.

Optionally, m is a positive integer, 1≤ n≤10, 10≤ (m+n)≤50. The inventors of the present disclosure discover that, a criticality is provided having the length of the main chain in this range, and an unexpected results can be achieved. By having the length of the main chain in this range, the reaction product of the reactant is in a range of molecular weight that results in a good solubility in the precured quantum dots block or the precured light scattering block. The reaction product is well dispersed in the precured quantum dots block or the light scattering block, without adversely affecting physical and chemical properties of the precured quantum dots block or the precured light scattering block. A substantially uniform thickness can be achieved in the quantum dots block or the light scattering block.

Optionally, R_{c} is substituted or unsubstituted alkylene (e.g. substituted or unsubstituted C₁ to C₂₀ alkylene), substituted or unsubstituted alkylene comprising an amide group, substituted or unsubstituted alkylene comprising an ester group, substituted or unsubstituted alkylene comprising a nitrogenous five-membered heterocycle, substituted or unsubstituted heteroalkylene (e.g. substituted or unsubstituted 2 to 20 membered heteroalkylene), substituted or unsubstituted cycloalkylene (e.g. C₃ to C₁₄ cycloalkylene including fused ring structures), substituted or unsubstituted heterocycloalkylene (e.g. 3 to 14 membered heterocycloalkyl including fused ring structures), substituted or unsubstituted arylene (e.g. a C₆ to C₁₄ aryl including fused ring structures), or substituted or unsubstituted heteroarylene (e.g. 5 to 14 membered heteroaryl including fused rings structures).

In one example, R_{c} is selected from the group consisting of a methylene group, an ethylene group, a propylene group, a butylene group, a pentylene group, and a hexatylene group.

In one example, R_{c} is selected from the group consisting of:

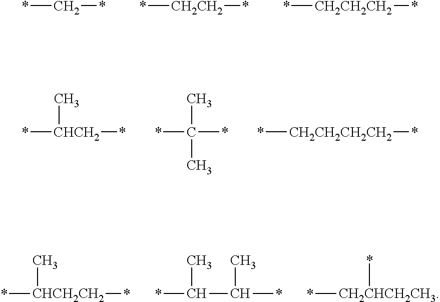

Optionally, R_{c} is selected from the group consisting of substituted or unsubstituted C₆ to C₁₈ alkylene,

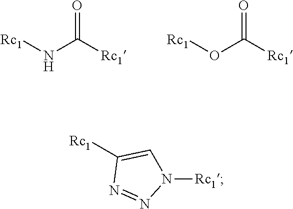

wherein Rc₁ and Rc₁′ are independently substituted or unsubstituted alkyl. Optionally, Rc₁ and Rc₁′ are independently substituted or unsubstituted C₆ to C₁₈ alkyl.

In one example, Rc₁ is selected from the group consisting of a methylene group, an ethylene group, a propylene group, a butylene group, a pentylene group, and a hexatylene group. In another example, Rc₁′ is selected from the group consisting of a methylene group, an ethylene group, a propylene group, a butylene group, a pentylene group, and a hexatylene group.

Optionally, R_{q} is selected from the group consisting of a carboxyl group (e.g., R-COOH), an amine group (e.g., R-NH2, R2-NH, R3-N), an amino group, a thiol group (e.g., R-SH), an ester group (e.g., R-COOR), a hydroxyl group (e.g., R—OH), a phosphorus group, a phosphine group (e.g., R3-P), a phosphinyloxy group (e.g., R3-PO), and a hydroxyphosphinyloxy group (e.g., RPO(OH)2 and R₂POOH).

Optionally, Rₓ is selected from the group consisting of:

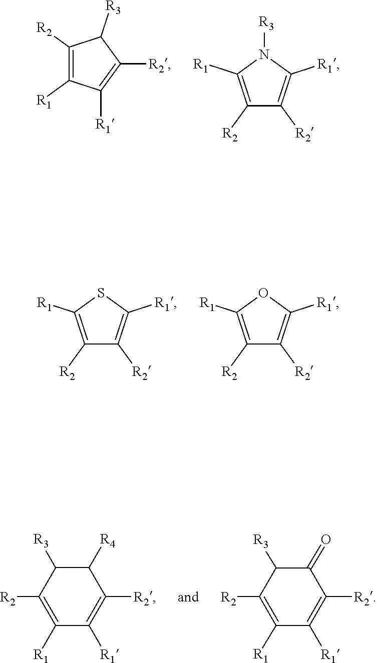

Optionally, one of R₁, R₁′, R₂, R₂′, R₃, and R₄ is connected to the main chain of the reactant, the one of R₁, R₁′, R₂, R₂′, R₃, and R₄ connected to the main chain of the reactant is substituted or unsubstituted alkylene (e.g. substituted or unsubstituted C₁ to C₂₀ alkylene), substituted or unsubstituted alkylene comprising an amide group, substituted or unsubstituted alkylene comprising an ester group, substituted or unsubstituted alkylene comprising a nitrogenous five-membered heterocycle, substituted or unsubstituted heteroalkylene (e.g. substituted or unsubstituted 2 to 20 membered heteroalkylene), substituted or unsubstituted cycloalkylene (e.g. C₃ to C₁₄ cycloalkylene including fused ring structures), substituted or unsubstituted heterocycloalkylene (e.g. 3 to 14 membered heterocycloalkyl including fused ring structures), substituted or unsubstituted arylene (e.g. a C₆ to C₁₄ aryl including fused ring structures), or substituted or unsubstituted heteroarylene (e.g. 5 to 14 membered heteroaryl including fused rings structures). The other five of R₁, R₁′, R₂, R₂′, R₃, and R₄ that are not connected to the main chain of the reactant are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures).

Optionally, the one of R₁, R₁′, R₂, R₂′, R₃, and R₄ connected to the main chain of the reactant is substituted or unsubstituted alkylene, substituted or unsubstituted alkylene comprising an amide group, substituted or unsubstituted alkylene comprising an ester group, substituted or unsubstituted alkylene comprising a nitrogenous five-membered heterocycle.

Optionally, the one of R₁, R₁′, R₂, R₂′, R₃, and R₄ connected to the main chain of the reactant is selected from the group consisting of a methylene group, an ethylene group, a propylene group, a butylene group, a pentylene group, and a hexatylene group. Examples of one of R₁, R₁′, R₂, R₂′, R₃, and R₄ connected to the main chain of the reactant include

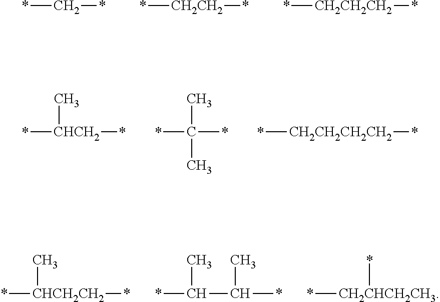

Optionally, the one of R₁, R₁′, R₂, R₂′, R₃, and Ry connected to the main chain of the reactant is selected from the group consisting of:

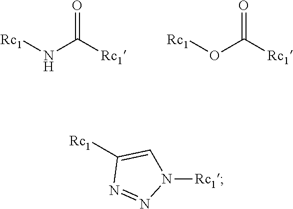

wherein Rc₁ and Rc₁′ are independently substituted or unsubstituted alkylene. Optionally, Rc₁ is selected from the group consisting of a methylene group, an ethylene group, a propylene group, a butylene group, a pentylene group, and a hexatylene group. Optionally, Rc₁′ is selected from the group consisting of a methylene group, an ethylene group, a propylene group, a butylene group, a pentylene group, and a hexatylene group.

Optionally, the other five of R₁, R₁′, R₂, R₂′, R₃, and R₄ that are not connected to the main chain of the reactant are independently hydrogen, a methyl group, a methylene group, an ethyl group, and an ethylidene group.

Various appropriate methods may be utilized to chelate the reactant to the quantum dots. In some embodiments, the chelating may be achieved by ligand exchange. In one specific example, a second quantum dots solution comprising a plurality of quantum dots are provided. Typically, the quantum dots in the second quantum dots solution is dissolved in organic solvents such as hexane, heptane, and octane. In the second quantum dots solution, ligands such as oleic acid, oleylamine, octylamine, thiol, trioctyl phosphine oxide are chelated to the quantum dots. The method includes drying the second quantum dots solution to remove the solvent therein, e.g., by blow-dried, drained, or spin-dried. Subsequent to the drying, a new solvent (e.g., toluene, xylene, chloroform, dichloromethane, or a mixture thereof) is added to dissolve the quantum dots in a concentration of 5 mg/ml to 30 mg/ml. Subsequent to the dissolving step, the reactant having the quantum dots chelating group and the conjugated diene functional group is added to the solution, and the solution is stirred for 4 to 8 hours at room temperature to allow chelating between the reactant and the quantum dots. Subsequently, the solution is added into methanol to precipitate the quantum dots, thereby obtaining the reactant chelated to the quantum dots.

In some embodiments, the one or more reactants include a first reactant having a conjugated diene functional group, and a quantum dots chelating group chelated to a quantum dots. Optionally, the one or more reactants further include a second reactant having a bis dienophile functional group. Optionally, the second reactant is not chelated to a quantum dots, and does not include a quantum dots chelating group.

In some embodiments, a reaction product (e.g., a Diels-Alder reaction product) of the first reactant is chelated to a quantum dots. In some embodiments, a reaction product (e.g., a Diels-Alder reaction product) of the second reactant is chelated to a quantum dots because the Diels-Alder reaction is a reaction between the first reactant and the second reactant.

In some embodiments, the reaction is a Diels-Alder reaction. Optionally the Diels-Alder reaction is a reaction between a reactant having a bis dienophile functional group and a reactant having a conjugated diene functional group. An example of the Diels-Alder reaction is provided below:

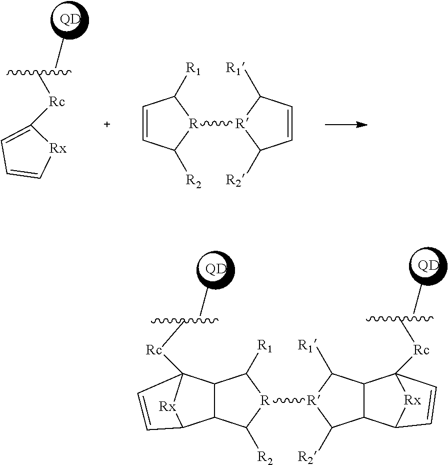

In some embodiments, the one or more products of the one or more reactants include a Diels-Alder reaction product of a reactant having a bis dienophile functional group and a reactant having a conjugated diene functional group.

In some embodiments, the one or more reactants include a first reactant having a bis dienophile functional group, and a quantum dots chelating group chelated to a first quantum dots. Optionally, the one or more reactants further include a second reactant having a conjugated diene functional group, and a quantum dots chelating group chelated to a second quantum dots.

In some embodiments, the reaction is a Diels-Alder reaction. Optionally the Diels-Alder reaction is a reaction between a reactant having a bis dienophile functional group and a reactant having a conjugated diene functional group. An example of the Diels-Alder reaction is provided below:

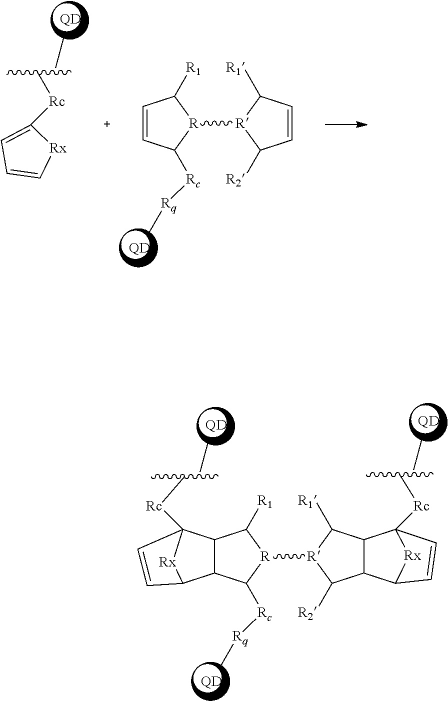

In some embodiments, the one or more products of the one or more reactants include a Diels-Alder reaction product of a reactant having a bis dienophile functional group and a reactant having a conjugated diene functional group.

In another aspect, the present disclosure provides a display apparatus, including the display panel described herein or fabricated by a method described herein, and one or more integrated circuits connected to the display panel. Examples of appropriate display apparatuses include, but are not limited to, an electronic paper, a mobile phone, a tablet computer, a television, a monitor, a notebook computer, a digital album, a GPS, etc.

In another aspect, the present disclosure provides a method of fabricating a display panel. In some embodiments, the method includes forming a quantum dots layer. In some embodiments, forming the quantum dots layer includes disposing a quantum dots ink solution into a plurality of first apertures; precuring the quantum dots ink solution in the plurality of first aperture to obtain a plurality of precured quantum dots blocks; initiating a respective reaction in a first region of a respective precured quantum dots block of the plurality of precured quantum dots blocks without initiating the respective reaction in a second region of the respective precured quantum dots block; and curing the plurality of precured quantum dots blocks subsequent to the respective reaction, thereby obtaining a plurality of quantum dots blocks respectively in the plurality of first apertures. Optionally, an average thickness of the first region is substantially the same as an average thickness of the second region.

In some embodiments, a concentration of a respective product of a respective reactant produced by a respective reaction in the first region of a respective quantum dots block of the plurality of quantum dots blocks is greater than a concentration of the respective product of the respective reactant produced by the respective reaction in the second region of the respective quantum dots block. Optionally, the respective reaction is one of a dimerization, oligomerization, polymerization, a condensation reaction, or any combination thereof.

In some embodiments, the respective reaction is initiated without using a chemical initiator. In some embodiments, the reaction is one that initiated by a non-chemical initiator. Examples of non-chemical initiators include light, heat, pressure, an electrical signal, microwave, and ultrasound. Accordingly, in some embodiments, the quantum dots layer or the light scattering layer is absent of any chemical initiator (e.g., a photo-initiator molecule) or reaction product thereof.

In some embodiments, a ratio of the respective reactant to the respective product in the second region is greater than a ratio of the respective reactant to the respective product in the first region.

In some embodiments, the respective reactant is a molecule comprising a dienophile functional group.

In some embodiments, the respective reactant is a molecule comprising a conjugated diene functional group.

In some embodiments, the respective reaction is dimerization, and the respective product is a dimerization product of a molecule comprising a dienophile functional group.

In some embodiments, the respective reaction is a Diels-Alder reaction, and the respective product is a product of the Diels-Alder reaction between a molecule comprising a dienophile functional group and a molecule comprising a conjugated diene functional group.

In some embodiments, the respective quantum dots block comprises a first respective product produced by a dimerization reaction and a second respective product produced by a Diels-Alder reaction. Optionally, a concentration of the first respective product in the first region is greater than a concentration of the first respective product in the second region. Optionally, a concentration of the second respective product in the first region is greater than a concentration of the second respective product in the second region.

In some embodiments, the respective reactant is chelated to a quantum dots.

In some embodiments, the respective reactant comprises a dienophile functional group and a quantum dots chelating group.

In some embodiments, the respective reactant comprises a conjugated diene functional group and a quantum dots chelating group.

In some embodiments, the respective product is chelated to a quantum dots.

In some embodiments, the second region substantially surrounds the first region. Optionally, the bank layer substantially surrounds the second region R2, the second region R2 substantially surrounds the first region R1, and the second region R2 spaces apart the first region R1 from the bank layer.

In some embodiments, the method includes forming a light scattering layer. In some embodiments, forming the light scattering layer includes disposing a light scattering ink solution into a plurality of second apertures; precuring the light scattering ink solution in the plurality of second aperture to obtain a plurality of precured light scattering blocks; initiating the respective reaction in a third region of a respective precured light scattering block of the plurality of precured light scattering blocks without initiating the respective reaction in a fourth region of the respective precured light scattering block; and curing the plurality of precured light scattering blocks subsequent to the respective reaction, thereby obtaining a plurality of light scattering blocks respectively in the plurality of second apertures. Optionally, a concentration of a respective product of a respective reactant produced by a respective reaction in the third region of a respective light scattering block of the plurality of light scattering blocks is greater than a concentration of the respective product of the respective reactant produced by the respective reaction in the fourth region of the respective light scattering block.

In some embodiments, a ratio of the respective reactant to the respective product in the fourth region is greater than a ratio of the respective reactant to the respective product in the third region.

In some embodiments, the respective light scattering block comprises a first respective product produced by a dimerization reaction and a second respective product produced by a Diels-Alder reaction. Optionally, a concentration of the first respective product in the third region is greater than a concentration of the first respective product in the fourth region. Optionally, a concentration of the second respective product in the third region is greater than a concentration of the second respective product in the fourth region.

In some embodiments, the fourth region substantially surrounds the third region. Optionally, the bank layer substantially surrounds the fourth region R4, the fourth region R4 substantially surrounds the third region R3, and the fourth region R4 spaces apart the third region R3 from the bank layer.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display substrate, comprising a quantum dots layer having a plurality of quantum dots;
wherein the quantum dots layer comprises a plurality of quantum dots blocks respectively in a plurality of first apertures;
a respective quantum dots block of the plurality of quantum dots blocks comprises a first region and a second region;
a concentration of a respective product of a respective reactant produced by a respective reaction in the first region is greater than a concentration of the respective product of the respective reactant produced by the respective reaction in the second region; and
the respective reaction is one of a dimerization, oligomerization, polymerization, a condensation reaction, or any combination thereof.

2. The display substrate of claim 1, wherein a ratio of the respective reactant to the respective product in the second region is greater than a ratio of the respective reactant to the respective product in the first region.

3. The display substrate of claim 1, wherein the respective reactant is a molecule comprising a dienophile functional group.

4. The display substrate of claim 1, wherein the respective reactant is a molecule comprising a conjugated diene functional group.

5. The display substrate of claim 1, wherein the respective reaction is dimerization, and the respective product is a dimerization product of a molecule comprising a dienophile functional group.

6. The display substrate of claim 1, wherein the respective reaction is a Diels-Alder reaction, and the respective product is a product of the Diels-Alder reaction between a molecule comprising a dienophile functional group and a molecule comprising a conjugated diene functional group.

7. The display substrate of claim 1, wherein the respective quantum dots block comprises a first respective product produced by a dimerization reaction and a second respective product produced by a Diels-Alder reaction;
a concentration of the first respective product in the first region is greater than a concentration of the first respective product in the second region; and
a concentration of the second respective product in the first region is greater than a concentration of the second respective product in the second region.

8. The display substrate of claim 1, wherein the respective reactant is chelated to a quantum dots.

9. The display substrate of claim 1, wherein the respective reactant comprises a dienophile functional group and a quantum dots chelating group.

10. The display substrate of claim 1, wherein the respective reactant comprises a conjugated diene functional group and a quantum dots chelating group.

11. The display substrate of claim 1, wherein the respective product is chelated to a quantum dots.

12. The display substrate of claim 1, further comprising a bank layer defining the plurality of first apertures;
wherein the bank layer substantially surrounds the second region;
the second region substantially surrounds the first region; and
the second region spaces apart the first region from the bank layer.

13. The display substrate of claim 1, further comprising a light scattering layer;
wherein the light scattering layer comprises a plurality of light scattering blocks respectively in a plurality of second apertures;
a respective light scattering block of the plurality of light scattering blocks includes a third region and a fourth region; and
the concentration of the respective product in the third region is greater than the concentration of the respective product in the fourth region.

14. The display substrate of claim 1, wherein the respective reactant comprises a bis dienophile functional group selected from the group consisting of: 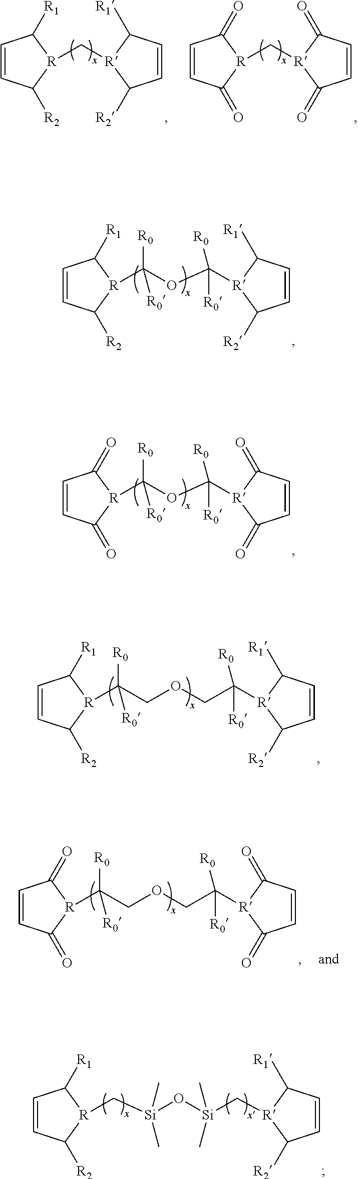
wherein R is nitrogen or —CH; R′ is nitrogen or —CH; R₀, R₀′, R₁, R₁′, R₂, R₂′ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl; and
x and x′ are independently a positive integer equal to or greater than 2.

15. The display substrate of claim 1, wherein the respective reactant comprises a bis dienophile functional group selected from the group consisting of: 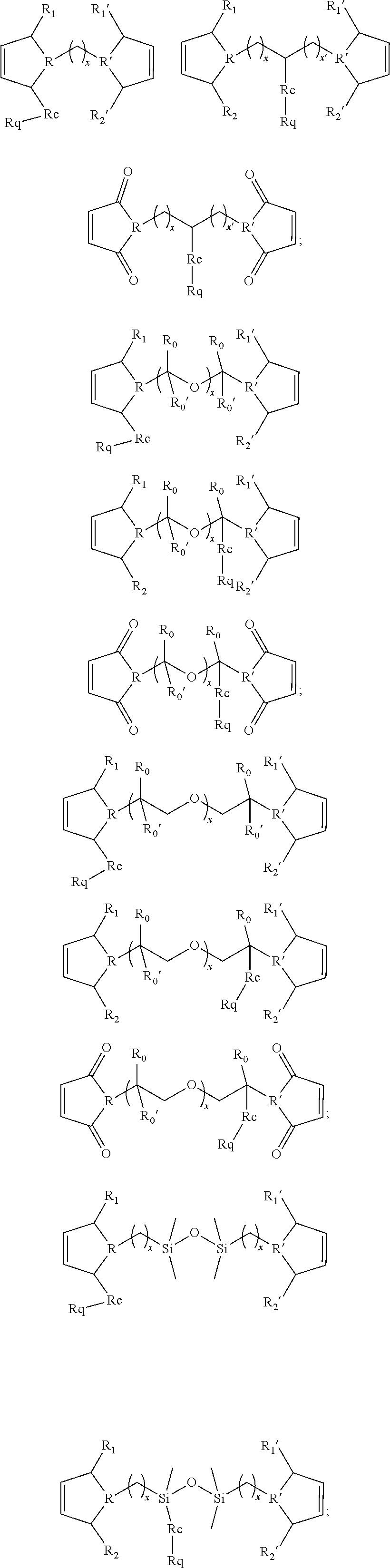
wherein R is nitrogen or —CH; R′ is nitrogen or —CH; R₀, R₀′, R₁, R₁′, R₂, R₂′ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl;
x and x′ are independently a positive integer equal to or greater than 2;
R_{c} is substituted or unsubstituted alkylene, substituted or unsubstituted alkylene comprising an amide group, substituted or unsubstituted alkylene comprising an ester group, substituted or unsubstituted alkylene comprising a nitrogenous five-membered heterocycle, substituted or unsubstituted heteroalkylene, substituted or unsubstituted cycloalkylene, substituted or unsubstituted heterocycloalkylene, substituted or unsubstituted arylene, or substituted or unsubstituted heteroarylene; and
R_{q} stands for a quantum dots chelating group.

16. The display substrate of claim 1, wherein the respective reactant comprises a conjugated diene functional group selected from the group consisting of: 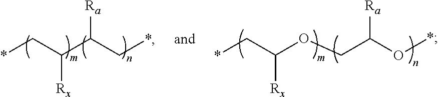
wherein Rₓ stands for the conjugated diene functional group, the one or more reactants further includes a main chain, the conjugated diene functional group Rₓ is connected to the main chain;
m is a positive integer, n is zero or a positive integer, 10≤ (m+n)≤100; and
Rₐ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

17. The display substrate of claim 16, wherein Rₐ is selected from the group consisting of hydrogen, substituted or unsubstituted C₁ to C₂₀ alkyl, or substituted or unsubstituted phenyl;
Rₓ is selected from the group consisting of: 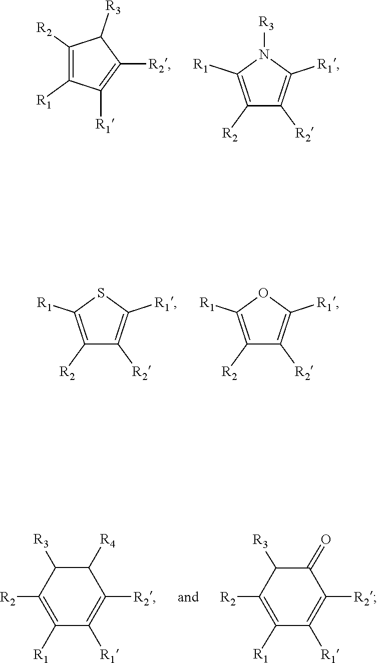
wherein one of R₁, R₁′, R₂, R₂′, R₃, and R₄ is connected to the main chain of the reactant;
the one of R₁, R₁′, R₂, R₂′, R₃, and R₄ connected to the main chain of the reactant is substituted or unsubstituted alkylene, substituted or unsubstituted alkylene comprising an amide group, substituted or unsubstituted alkylene comprising an ester group, substituted or unsubstituted alkylene comprising a nitrogenous five-membered heterocycle; and
the other five of R₁, R₁′, R₂, R₂′, R₃, and R₄ that are not connected to the main chain of the reactant are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

18. The display substrate of claim 1, wherein the respective reactant comprises a conjugated diene functional group selected from the group consisting of: 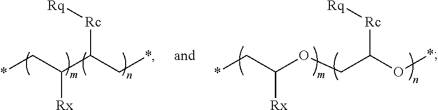
wherein Rₓ stands for the conjugated diene functional group, the one or more reactants further includes a main chain, the conjugated diene functional group Rₓ is connected to the main chain;
m is a positive integer, n is a positive integer, 1≤ n≤10, 10≤ (m+n)≤50;
R_{c} is substituted or unsubstituted alkylene, substituted or unsubstituted alkylene comprising an amide group, substituted or unsubstituted alkylene comprising an ester group, substituted or unsubstituted alkylene comprising a nitrogenous five-membered heterocycle, substituted or unsubstituted heteroalkylene, substituted or unsubstituted cycloalkylene, substituted or unsubstituted heterocycloalkylene, substituted or unsubstituted arylene, or substituted or unsubstituted heteroarylene; and
R_{q} stands for a quantum dots chelating group.

19. (canceled)

20. A display apparatus, comprising the display substrate of claim 1, and a light emitting substrate.

21. A method of fabricating a display substrate, comprising forming a quantum dots layer having a plurality of quantum dots;
wherein forming the quantum dots layer comprises:
disposing a quantum dots ink solution into a plurality of first apertures;
precuring the quantum dots ink solution in the plurality of first aperture to obtain a plurality of precured quantum dots blocks;
initiating a respective reaction in a first region of a respective precured quantum dots block of the plurality of precured quantum dots blocks without initiating the respective reaction in a second region of the respective precured quantum dots block; and
curing the plurality of precured quantum dots blocks subsequent to the respective reaction, thereby obtaining a plurality of quantum dots blocks respectively in the plurality of first apertures;
wherein a concentration of a respective product of a respective reactant produced by a respective reaction in the first region of a respective quantum dots block of the plurality of quantum dots blocks is greater than a concentration of the respective product of the respective reactant produced by the respective reaction in the second region of the respective quantum dots block; and
the respective reaction is one of a dimerization, oligomerization, polymerization, a condensation reaction, or any combination thereof.
